(19) United States
(12) Patent Application Publication
(10) Pub. No.: US 2026/0009125 A1
(43) Pub. Date: Jan. 8, 2026

(54) Heteroleptic Triazenide Metal Complexes

(71) Applicant: Dockweiler Chemicals Gmbh, Marburg (DE)

(72) Inventors: Markus Balmer, Kirchhain (DE); Oliver Briel, Alzenau (DE); Manuel Kapitein, Marburg (DE); Susanne Elisa Herritsch, Marburg (DE)

(21) Appl. No.: 19/130,111

(22) PCT Filed: Jul. 21, 2024
(86) PCT No.: PCT/DE2024/100649

§ 371 Date: May 14, 2025

(30) Foreign Application Priority Data
Jul. 21, 2023 (DE) 102023119428.3

(51) Int. Cl. C23C 16/18; C07F 17/00; C23C 16/34; C23C 16/40; C23C 16/455

(52) U.S. Cl. CPC C23C 16/18; C07F 17/00; C23C 16/34; C23C 16/405; C23C 16/45553

(57) ABSTRACT

The invention relates to metal complexes according to the formula [M(LC)(LT)(LZ)]. Thereby applies: M=scandium, yttrium, lanthanide or titanium; LC=unsubstituted, monoalkyl-substituted or polyalkyl-substituted cyclopentadienide anion; LT=triazenide anion (R1-N3-R2)-, wherein R1 and R2 are independently of each another a linear alkyl group with 1 to 10 carbon atoms or a branched alkyl group with 3 to 10 carbon atoms; LZ is a) independently of LC selected from the group mentioned for LC, or b) independently of LT selected from the group mentioned for LT. Subject matter of the invention is, in addition, the use of at least one such metal complex for producing a layer consisting of at least one metal M or containing at least one metal M on a surface of a substrate as well as for producing an electronic component.

Homoleptic and heteroleptic metal complexes exhibiting at least one nitrogen-containing ligand, methods for their preparation as well as their use as precursors in chemical vapour deposition processes are known in the prior art.

In the field of electrotechnology, particularly in the field of semiconductor technology, the production of highly pure layers, which, for example, comprise a lanthanide (III) oxide, a lanthanide (III)-containing mixed oxide or a lanthanide (Ln) containing III-V compound semiconductor or consist of such a material, is increasingly becoming the focus of interest. The deposition of such metal layers or metal-containing layers on surfaces of substrates can be carried out, for example, by means of metal organic chemical vapour deposition (MOCVD), atomic layer deposition (ALD) or metal organic chemical vapour phase epitaxy (MOVPE).

At this point and in the following, the indication of an exact stoichiometry of a metal layer, a metal film, a metal-containing layer or a metal-containing film is renounced. The terms layer and film are used synonymously, whereat none of these words includes an indication regarding the layer thickness or the film thickness. In US 2014/0335702 A1 lanthanide-containing precursors according to the general formula Ln(R¹Cp)ₘ(R²—N—C(R⁴)═N—R²)ₙ as well as a method of depositing a lanthanide-containing film on a semiconductor substrate using such a precursor are disclosed. Thereby applies: Ln=Sc, Y, La, Ce, Pr, Nd, Sm, Eu, Gd, Tb, Dy, Ho, Er, Tm, Yb, Lu; R¹ and R² are independently of each other selected from the group consisting of H and C1-C5 alkyl chains; R⁴=H or Me; m and n are in the range from 1 to 2. And each precursor has a melting point below about 105° C. Examples of embodiments are exclusively shown for m=2 and n=1, thus, only for Ln (III) complexes, each of which comprising two monosubstituted cyclopentadienyl ligands, whereat R¹=Me, Et or iPr, and one amidinate ligand. The given synthesis procedures predominantly concern precursors, each of which having an N,N′-dialkyl-substituted acetamidinate ligand, whereat R¹=R²=iPr or tBu and R⁴=Me. Further procedures are formulated for the preparation of complexes with an N,N′-dialkyl-substituted formamidinate ligand each, whereat R¹=R²=iPr and R⁴=H.

Unfavourable at these Ln (III) complexes having one or two amidinate ligands, in particular at least one acetamidinate ligand, is the carbon contained in the N—C(R⁴)=N skeleton of the ligand. This applies particularly with a view to the use of these heteroleptic Ln (III) complexes as precursors in chemical vapour deposition processes. Because there exists a not inconsiderable probability that the produced Ln layer or Ln-containing layer is contaminated by carbon and is therefore useless for the intended application each, particularly in the semiconductor sector.

WO 2019/115646 A1 relates to metal complexes having at least one ligand L of the formula R¹—N₃—R², whereat R¹ and R² are hydrocarbon radicals, as well as their use for depositing the metal or a compound of the metal from the gas phase. For the group of lanthanides two examples are shown: [La(tBu-N₃-tBu)₃] (cf. page 37, Example 10) and [Ce(tBu-N₃-tBu)₃] (cf. page 52, Example 28). These homoleptic lanthanide (III) complexes each have a relatively high molecular weight of more than 600 g/mol (approx. 608 g/mol).

Whereas the preparation of the homoleptic cerium (III) complex was conducted by reacting CeCl₃ with Li (tBu-N₃-tBu), the homoleptic lanthanum (III) complex was prepared starting from [La(hmds)₃] (hmds=hexamethyldisilazide) and (Bu-HN₃-tBu. According to thermogravimetric analysis the product still contained residual traces of hexamethyldisilazide; a melting process set from a temperature of 103° C. (cf. page 38).

The melting temperature of approx. 100° C. and, in particular, the relatively high molecular weight of more than 600 g/mol suggest the assumption that this lanthanum (III) triazenide complex has a relatively low vapour pressure. A material having the aforementioned properties and a low volatility usually accompanied therewith is rather unfavourable for the use as a precursor in a chemical vapour deposition process (cf. also WO 2019/115646 A1, claim 21). The reasons for this are manifold: On the one hand, when using a low volatile material, process conditions are generally required which result in a quality of the produced metal layer or metal-containing layer being insufficient for many end applications. In particular, high temperatures are necessary, for the production of which, unfavourably, an elaborate and therefore cost-intensive heating system is required. The additional instrumental effort as well as the increased energy consumption have a negative impact on the economic and ecological balance of the process. In case of the thermal decomposition of a homoleptic precursor such as [La(tBu-N₃-tBu)₃] an increased incorporation of parasitic impurities into the semiconductor layer may occur in addition, for example in the form of carbon, by which the quality of the layer is further deteriorated.

In the light of the foregoing, the pre-known precursor materials for chemical vapour deposition processes are to be classified as unsatisfactory under ecological and (atom) economical aspects.

The object underlying the invention is therefore to overcome these and further disadvantages of the state of the art and to provide metal complexes which contain a metal relevant for the electrical industry, particularly for the semiconductor industry, namely scandium, yttrium, a lanthanide or titanium, and which meet the requirements placed on precursor materials for chemical vapour deposition processes. In particular, the metal complexes should be characterised by a high purity and a relatively high vapour pressure and be suitable as precursors for the production of metal layers or metal-containing layers of high quality. In addition, the metal complexes should be producible straight-forwardly, efficiently, reproducibly and as cost-efficiently as possible in high purity and in good yields, even on an industrial scale. Furthermore, the invention relates to a method for producing a layer which consists of at least one metal or contains at least one metal on a surface of a substrate using at least one of the here presented metal complexes, wherein the metal is scandium, yttrium, a lanthanide or titanium. Subject matter of the invention is, in addition, a substrate exhibiting on a surface at least one layer, which consists of at least one metal or containing at least one metal, wherein the metal is as defined above and wherein the respective layer is produced using at least one of the here presented metal complexes. Moreover, a method for producing an electronic component using at least one of the here presented metal complexes should be provided.

The object is solved by a metal complex according to the general formula

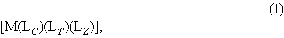

wherein
i. M is a metal central atom selected from the group consisting of scandium (Sc), yttrium (Y), lanthanides and titanium (Ti),
ii. L_{C} is a monoanionic pi-donor ligand selected from the group consisting of
   unsubstituted cyclopentadienide anion (C₅H₅⁻),
   monoalkyl-substituted cyclopentadienide anions according to the general formula R^{A}Cp⁻, wherein
   R^{A} is selected from the group consisting of linear alkyl groups with 1 to 10 carbon atoms and branched alkyl groups with 3 to 10 carbon atoms, and
   polyalkyl-substituted cyclopentadienide anions according to the general formula R^{B}R^{C}R^{D}R^{E}R^{F}Cp⁻, wherein
   the radicals R^{B}, R^{C}, R^{D}, R^{E} and R^{F} are independently of each other selected from the group consisting of hydrogen (H), linear alkyl groups with 1 to 10 carbon atoms and branched alkyl groups with 3 to 10 carbon atoms,
   with the proviso that at least two of the radicals R^{B}, R^{C}, R^{D}, R^{E} and R^{F} are unequal hydrogen (H);
iii. L_{T} is a triazenide anion according to the general formula (R¹—N₃—R²)—, wherein the radicals R¹ and R² are independently of each other selected from the group consisting of linear alkyl groups with 1 to 10 carbon atoms and branched alkyl groups with 3 to 10 carbon atoms;
and
iv. L_{Z} is a
   a) monoanionic pi-donor ligand which is, independently of the monoanionic pi-donor ligand L_{C}, selected from the group consisting of
      unsubstituted cyclopentadienide anion (C₅H₅⁻),
      monoalkyl-substituted cyclopentadienide anions according to the general formula R^{A}Cp⁻, wherein
      R^{A} is selected from the group consisting of linear alkyl groups with 1 to 10 carbon atoms and branched alkyl groups with 3 to 10 carbon atoms, and
      polyalkyl-substituted cyclopentadienide anions according to the general formula R^{B}R^{C}R^{D}R^{E}R^{F}Cp⁻, wherein
      the radicals R^{B}, R^{C}, R^{D}, R^{E} and R^{F} are independently of each other selected from the group consisting of hydrogen (H), linear alkyl groups with 1 to 10 carbon atoms and branched alkyl groups with 3 to 10 carbon atoms, with the proviso that at least two of the radicals R^{B}, R^{C}, R^{D}, R^{E} and R^{F} are unequal hydrogen (H);
   or
   b) triazenide anion according to the general formula (R¹—N₃—R²)—, wherein the radicals R¹ and R² are independently of each other and independently of the triazenide anion L_{T} selected from the group consisting of linear alkyl groups with 1 to 10 carbon atoms and branched alkyl groups with 3 to 10 carbon atoms.

The general formula [M(L_{C})(L_{T})(L_{Z})] (I) includes both mononuclear and polynuclear metal complexes.

In connection with the present invention, the term “lanthanides” means the group consisting of lanthanum and the 14 elements following lanthanum with the atomic numbers 58 to 71: cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu). Together with the lighter homologues of lanthanum, that is scandium (Sc) and yttrium (Y), the lanthanides are referred to as “rare earth metals”.

It should be pointed out that in a metal complex according to the general formula [M(L_{C})(L_{T})(L_{Z})] (I), wherein L_{Z} is a monoanionic pi-donor ligand, it may be provided that the monoanionic pi-donor ligand L_{C} and the monoanionic pi-donor ligand L_{Z} are different or identical. And in a metal complex according to the general formula [M(L_{C})(L_{T})(L_{Z})] (I), wherein L_{Z} is a triazenide anion according to the general formula (R¹—N₃—R²), the triazenide anion L_{T} and the triazenide anion L_{Z} may be different or identical.

The radical R^{A} may also be selected from the group consisting of linear alkyl groups with 1 to 9 carbon atoms and branched alkyl groups with 3 to 9 carbon atoms, more advantageously from the group consisting of linear alkyl groups with 1 to 8 carbon atoms and branched alkyl groups with 3 to 8 carbon atoms, even more advantageously from the group consisting of linear alkyl groups with 1 to 7 carbon atoms and branched alkyl groups with 3 to 7 carbon atoms, in particular from the group consisting of linear alkyl groups with 1 to 6 carbon atoms and branched alkyl groups with 3 to 6 carbon atoms.

The polyalkyl-substituted cyclopentadienide anion according to the general formula R^{B}R^{C}R^{D}R^{E}R^{F}Cp⁻ is an at least doubly alkyl-substituted cyclopentadienide anion. It may also be a threefoldly alkyl-substituted or a fourfoldly alkyl-substituted or a fivefoldly akly-substituted cyclopentadienide anion. Particularly in the latter case it is advantageous if the radicals R^{B}, R^{C}, R^{D}, R^{E} and R^{F} are identical. Then the monoanionic pi-donor ligand is in the simplest case the 1,2,3,4,5-pentamethylcyclopentadienide anion, whereat R^{B}=R^{C}=R^{D}=R^{E}=R^{F}=methyl applies (C₅Me₅⁻; Cp*).

The radicals R^{B}, R^{C}, R^{D}, R^{E} and R^{F} may also be selected independently of each other from the group consisting of hydrogen (H), linear alkyl groups with 1 to 9 carbon atoms and branched alkyl groups with 3 to 9 carbon atoms, more advantageously from the group consisting of hydrogen (H), linear alkyl groups with 1 to 8 carbon atoms and branched alkyl groups with 3 to 8 carbon atoms, even more advantageously from the group consisting of hydrogen (H), linear alkyl groups with 1 to 7 carbon atoms and branched alkyl groups with 3 to 7 carbon atoms, in particular from the group consisting of hydrogen (H), linear alkyl groups with 1 to 6 carbon atoms and branched alkyl groups with 3 to 6 carbon atoms, in each case with the proviso that at least two of the radicals RB, R^{C}, R^{D}, R^{E} and R^{F} are unequal hydrogen (H).

The radical R¹ and the radical R² may also be selected independently of each other from the group consisting of linear alkyl groups with 1 to 9 carbon atoms and branched alkyl groups with 3 to 9 carbon atoms, advantageously from the group consisting of linear alkyl groups with 1 to 8 carbon atoms and branched alkyl groups with 3 to 8 carbon atoms, more advantageously from linear alkyl groups with 1 to 7 carbon atoms and branched alkyl groups with 3 to 7 carbon atoms, even more advantageously from the group consisting of linear alkyl groups with 1 to 6 carbon atoms and branched alkyl groups with 3 to 6 carbon atoms.

The here presented metal complexes according to formula I are advantageously reproducibly producible by means of a straight-forward, (atom) efficient and comparatively inexpensively performable synthesis. In fact, in high purity that meets the requirements placed on precursor materials for chemical vapour deposition processes, and in good to very good yield as well as in good space-time yield, in fact, also on a commercial scale. The compounds according to formula I can principally be applied in all processes of chemical vapour deposition (CVD). In particular, these are MOCVD processes, MOVPE processes and ALD processes.

The preparation of the metal complexes of the type [M(L_{C})(L_{T})(L_{Z})] (I) is carried out starting from an anhydrous metal (III) halide and an alkali metal cyclopentadienide in an aprotic polar solvent, in particular an ether, for example in THF or in Et₂O. The metal (III) halide, in particular a metal (III) chloride, is advantageously present as-in situ generated, if applicable-THE adduct.

The term “in situ preparation” and “in situ generation”, respectively, means that the starting materials which are required for the synthesis of a compound to be produced in this way and of an intermediate to be produced in this way, respectively, are made to react in a suitable stoichiometry in a solvent or solvent mixture and the product forming thereby is not isolated. Rather, the solution or the suspension, which comprises the in situ generated intermediate, is further used directly, i.e. without isolation and/or further purification.

The product of the first salt metathetic reaction, for example [(EtCp)₂YCl], can advantageously be reacted directly, i.e. without isolation and/or purification, with a lithium triazenide to the desired product according to formula I, for example [(EtCp)₂Y(tBu-N₃—(Bu)]. For this step, it is particularly advantageous to choose an aprotic non-polar solvent, for example toluene. Then the lithium halide, in particular LiCl, generated as the only by-product, can be separated quantitatively or almost quantitatively in an easily and quickly implementable filtration step and/or decantation step and/or centrifugation step. The removal of the solvent is followed by an also easily and quickly implementable purification of the crude product by distillation and/or sublimation.

The compounds according to formula I are—according to ¹H NMR spectroscopic examination—usually obtained in a purity of at least 97%, advantageously of more than 97%, in particular of more than 98% or 99%. This is due to the fact that after the isolation and purification of the respective metal complex according to formula I, impurities may still be contained due to volatile organic compounds, in particular due to organic solvents used as part of the synthesis. According to experience this type of impurities is non-critical in respect of the use of the here described metal complexes in chemical vapour deposition processes. In other words: The quality of the metal layers or metal-containing layers to be deposited is usually not impaired by this type of impurities. In connection with the present invention, the term “high purity” and the term “highly pure” refer to a total content of impurities due to undesired metals, undesired semimetals, atmospheric oxygen and water of below 1 ppm, ideally of below 100 ppb. In the semiconductor industry, such a level of purity is referred to as electronic grade. Potential impurities of the type described above, i.e. due to volatile organic compounds, in particular due to organic solvents used as part of the synthesis, are not considered with this purity specification.

The yield of the here presented metal complexes according to formula I is generally ≥ 70%. When carrying out the process on an industrial scale, the target compounds are advantageously obtained in comparable yield and purity.

It is surprising that the here described metal complexes according to formula I are existent solvent-free after carrying out a simple purification step, namely a distillation or a sublimation. In other words: The metal complexes according to formula I, for example [(EtCp)Sc(tBu-N₃-tBu)₂] and [(EtCp)₂Y(tBu-N₃—(Bu)], are not obtained in the form of their solvent adducts and resolvent adducts, respectively. This is, in view of their use, especially as precursors for producing highly pure metal layers or metal-containing layers by means of processes of chemical vapour deposition, particularly advantageous. Surprising is the fact that the metal complexes according to formula I are existent solvent-free, especially because with lanthanide cations the low ratio between charge and radius usually results in high coordination numbers. While two cyclopentadienide anions and one amidinate anion according to the general formula (R^{X}—N—C(R^{Y})=N—R^{Z})⁻ can sufficiently shield the coordination sphere of Ln (III) cations (cf. US 2014/0335702 A1), this is not to be expected, for example, for a ligand regime consisting of two cyclopentadienide anions and one triazenide anion. Because a triazenide anion exhibits, especially compared to an amidinate anion, a relatively acute bite angle.

The here presented metal complexes of the type [M(L_{C})(L_{T})(L_{Z})] (I) are characterised by a heteroleptic complex design, whereat at least one triazenide ligand according to the general formula (R¹—N₃—R²)⁻ is provided. The skeleton of the triazenide ligand advantageously exhibits exclusively nitrogen, wherein the skeleton of the anionic N-donor ligand is stabilised by the two alkyl radicals R¹ and R². Due to the nitrogen-containing skeleton the risk, existing as part of a chemical vapour deposition process, that contaminated—particularly by carbon—and therefore of qualitatively unsatisfying layers are produced is clearly reduced. In addition, the incorporation of the desired elements, in particular the incorporation of nitrogen, into the layers to be produced is promoted, i.e. the incorporation rates of the desired elements are improved. It was found that this risk can be further reduced by the selection of the two terminal alkyl groups. Thus, when using the complex [(EtCp)₂Sc(tBu-N₃-tBu)] as precursor material in an MOVPE process, an even lower carbon incorporation rate was observed than when using complexes with sterically less demanding and less-carbon triazenide ligands, such as [(MeCp)₂Sc(R¹—N₃—R²)], wherein R¹=R²=Me or Et or iPr.

A further important advantage of the here presented complex type according to the general formula [M(L_{C})(L_{T})(L_{Z})] (I) is that a variety of different, particularly tailor-made, precursors can be provided in a very simple manner. Because, on the one hand, the ligand regime is variable, i.e. either a) a cyclopentadienide ligand L_{C}, a triazenide ligand L_{T} and a cyclopentadienide ligand L_{Z} can be provided for, or b) a cyclopentadienide ligand L_{C}, a triazenide ligand L_{T} and a triazenide ligand L_{Z}. And on the other hand, each of the three ligands L_{C}, L_{T} and L_{Z} is modifiable in manifold ways by variation of the residues RA, R^{B}, R^{C}, R^{D}, RE, RF, R¹ and R². This is particularly advantageous with a view to the different process conditions to which the precursor materials may be exposed, for example depending on the choice of the vapour deposition process. Tailor-made and application-specific optimised precursors, respectively, can thus be provided with comparatively little effort, namely simply by variation of the ligand regime and/or the substitution patterns of the three ligands L_{C}, L_{T} and L_{Z}. Thus, for example, an optimisation for the application in an MOCVD process or in an ALD process or in an MOVPE process can take place. In this context, it should be noted that the synthesis route outlined above can advantageously be treaded essentially independently of the desired metal central atom and of the ligand regime. In other words: Both the metal central atom and its ligand sphere can be varied over wide ranges, in particular by modification of the substitution patterns of the cyclopentadienide ligand(s) and the triazenide ligand(s), without the need to make essential changes to the synthesis protocol. Rather, if any, only minor changes to the synthesis protocol are required, for example in the form of a solvent change and/or a temperature adjustment.

Moreover, particularly advantageous is that the here presented metal complexes according to formula I usually have relatively low melting temperatures, generally of less than 100° C. or of less than 95° C. or of less than 90° C., for example of approx. 80° C. in the case of [(MeCp)₂Sc(tBu-N₃—(Bu)] or of approx. 40° C. in the case of [(EtCp)₂Y(tBu-N₃-tBu)]. In addition, metal complexes can be provided which have molecular weights of less than 600 g/mol, advantageously of at most 595 g/mol, in particular of less than 595 g/mol. Complexes according to formula I, wherein M=Sc, Y or Ti, can for example also have molecular weights of less than 550 g/mol or of less than 500 g/mol, for example in the range from 350 g/mol to 550 g/mol. This advantageously results—in conjunction with a low melting temperature—in a relatively high vapour pressure for the metal complexes described here.

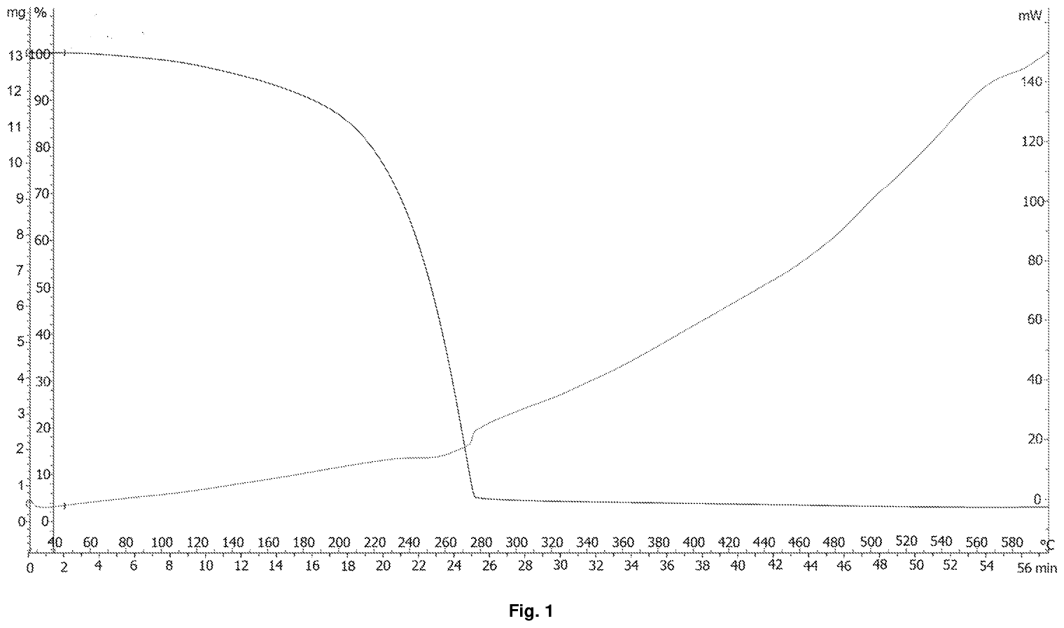

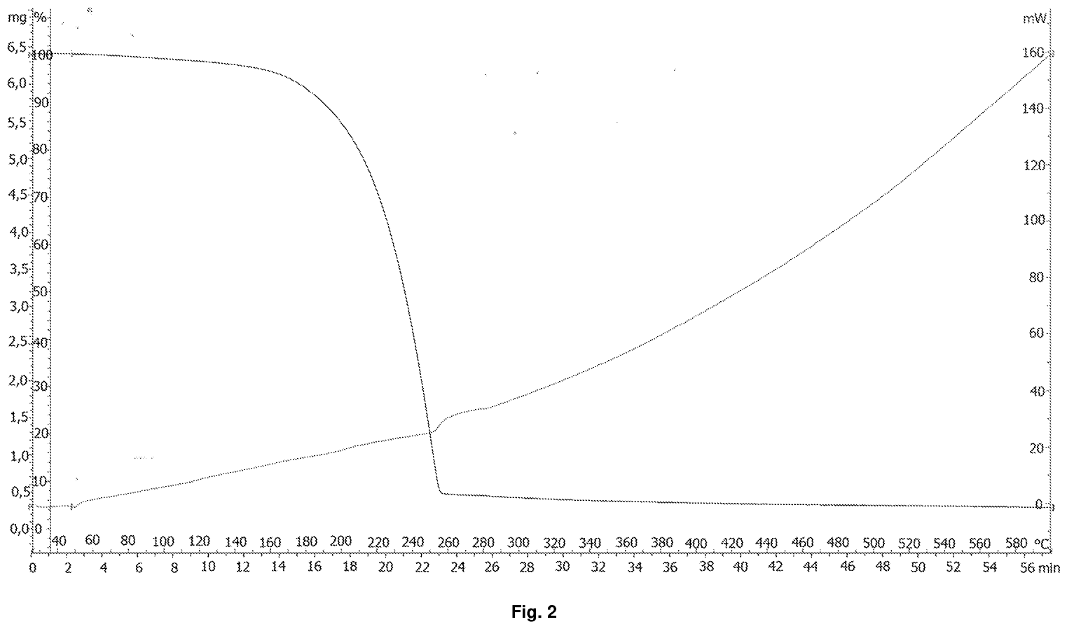

The thermogravimetric analysis (TGA) of selected metal complexes according to formula I, in particular of the complexes [(EtCp)₂Sc(tBu-N₃—(Bu)] and [(EtCp)Sc(tBu-N₃-tBu)₂] (cf. FIG. 1 and FIG. 2), had as a result that the transition of these precursor compounds into the gas phase occurs at relatively low temperatures. Particularly advantageous is that this transition also takes place without decomposition. Consequently, when using a complex of the here presented type as a precursor in a process of chemical vapour deposition, a targeted decomposition of the respective precursor can advantageously be conducted, in fact at relatively low process temperatures. Overall, a better availability of the precursors in the gas phase is thus achieved and finally an increase in the incorporation rate of the desired elements. In addition, the targeted decomposition at comparatively low process temperatures positively affects the layer growth. Consequently, the produced layers are of high quality as to their purity, their composition and their morphology.

In connection with the present invention, the term “layer of high quality” refers to the purity, the composition, in particular to the content of the respective metal M, and the morphology of a layer produced by means of a process of chemical vapour deposition.

Exemplary, the complex [(EtCp)₂Sc(tBu-N₃-tBu)] was used as precursor material in an MOVPE process to produce AlScN layers. The AlScN layers were deposited, for example, on a surface of a gallium nitride substrate (GaN substrate). The growth temperature was usually in the range of 900° C. to 1,200° C., the internal temperature of the bubbler, in German also known as a vapour pressure saturator, was generally approx. 50° C. to approx. 100° C. Surprisingly, a sufficiently high vapour pressure of the precursor was observed even at a relatively low internal temperature of the bubbler in the aforementioned range. A molar flow in the normally selected range was achieved by setting a hydrogen flow (carrier gas) that was comparable to the flow determined for the precursor. Layer growth rates in the expected range were achieved. Depending on the selected growth conditions in each case, in particular on the selected substrate, the internal temperature of the bubbler and the process temperature, the produced AlScN layers contained at least approx. 10 atomic percentage scandium, i.e. the scandium incorporation rate was at least approx. 10 atomic percentage. Consequently, the scandium content was at least comparable to the value of ≈10% recently reported by Streicher et al. (Phys. Status Solidi RRL 2023, 17, 2200387) for an AlScN layer. This layer was obtained by means of an MOCVD process using bis(methylcyclopentadienyl) scandium chloride ([(MeCp)₂ScCl]₂), in fact at a growth temperature of 900° C.

Surprisingly, when using the here presented complex [(EtCp)₂Sc(tBu-N₃-tBu)]—unlike in the case of the previously known precursor [(MeCp)₂ScCl]₂ also used by the inventors under identical process conditions—it was found that the scandium incorporation rate is not dependent on the growth temperature.

The percentage atomic composition of the AlScN layers produced in connection with this invention was determined in each case by means of high resolution transmission electron microscopy (HRTEM) in combination with energy dispersive X-ray analysis (EDXA) on a scanning transmission electron microscope (STEM).

To summarise, it can be stated that the here presented metal complexes according to the general formula [M(L_{C})(L_{T})(L_{Z})] (I) are producible highly pure in a straightforward manner in good to very good yields, even on an industrial scale. The heteroleptic, variable complex design, which provides for at least one ligand with a nitrogen-based, carbon-free skeleton (triazenide ligand), allows the provision of a variety of different metal complexes, which are advantageously tailor-made and application-specific optimised, respectively. Particularly advantageous is that the here described metal complexes of the type [M(L_{C})(L_{T})(L_{Z})] (I) meet all requirements placed on precursor materials for chemical vapour deposition processes and are thus predestined, in particular, for the use in processes of this type. Particularly advantageous is that the complex design of the compounds according to formula I leads to both the promotion of the incorporation of desired elements into the layer to be produced and the reduction of the incorporation of undesired elements, such as carbon. Advantageously, the use of these complexes can take place at ideal process temperatures so that metal layers and metal-containing layers of high quality can be produced. For example, layers that comprise or consist of a lanthanide-containing III-V compound semiconductor or a Ln oxide. Overall, from an (atomic) economical and ecological point of view the use of complexes of the here presented type in chemical vapour deposition processes is particularly advantageous.

In an advantageous embodiment of the here described metal complex, the lanthanide is selected from the group consisting of
i. La, Ce, Pr, Nd, Sm, Eu, Gd, Tb, Dy, Ho, Er, Tm, Yb and Lu;
or
ii. La, Ce, Pr, Nd, Sm, Eu, Gd, Tb, Er, Yb and Lu;
or
iii. La, Ce, Pr, Nd, Eu, Gd, Er, Yb and Lu.

In particular, the lanthanide is selected from the group consisting of La, Ce, Nd, Eu, Er and Lu.

According to another embodiment of the here presented metal complex it is provided that
i. the monoanionic pi-donor ligand L_{C} is selected from the group consisting of
   unsubstituted cyclopentadienide anion (C₅H₅⁻);
   monoalkyl-substituted cyclopentadienide anions according to the general formula R^{A}Cp⁻, wherein
   the radical R^{A} is selected from the group consisting of methyl, ethyl, propyl, butyl, pentyl, and their isomers, in particular from the group consisting of methyl, ethyl, n-propyl, iso-propyl, n-butyl, iso-butyl, sec-butyl and tert-butyl;
   polyalkyl-substituted cyclopentadienide anions according to the general formula R^{B}R^{C}R^{D}R^{E}R^{F}Cp⁻, wherein
   the radicals R^{B}, R^{C}, R^{D}, R^{E} and R^{F} are independently of each other selected from the group consisting of hydrogen (H), methyl, ethyl, propyl, butyl, pentyl, and their isomers, in particular from the group consisting of hydrogen (H), methyl, ethyl, n-propyl, iso-propyl, n-butyl, iso-butyl, sec-butyl and tert-butyl,
   with the proviso that at least two of the radicals R^{B}, R^{C}, R^{D}, R^{E} and R^{F} are unequal hydrogen (H);
and/or
ii. at least one of the radicals R¹ and R² of the triazenide anion L_{T} is selected from the group consisting of linear alkyl groups with 1 to 6 carbon atoms and branched alkyl groups with 3 to 6 carbon atoms.

It may also be provided that the monoanionic pi-donor ligand L_{C} is a polyalkyl-substituted cyclopentadienide anion according to the general formula R^{B}R^{C}R^{D}R^{E}R^{F}Cp⁻, wherein the radicals R^{B}, R^{C}, R^{D}, R^{E} and R^{F} are independently of each other selected from the group consisting of hydrogen (H), methyl, ethyl, propyl, butyl, pentyl, and their isomers, in particular from the group consisting of hydrogen (H), methyl, ethyl, n-propyl, iso-propyl, n-butyl, iso-butyl, sec-butyl and tert-butyl, with the proviso that at least two of the radicals R^{B}, R^{C}, R^{D}, R^{E} and RF, which are unequal hydrogen (H), are identical.

Then the pi-donor ligand L_{C} is, for example, Me₄Cp⁻ or Me(Et)₂Cp⁻ or Et₂Cp⁻ or Et₂(iBu)Cp⁻ or Me₅Cp⁻ (Cp*).

Furthermore, it may be provided that the monoanionic pi-donor ligand L_{C} is a polyalkyl-substituted cyclopentadienide anion according to the general formula R^{B}R^{C}R^{D}R^{E}R^{F}Cp⁻, wherein the radicals R^{B}, R^{C}, R^{D}, R^{E} and R^{F} are independently of each other selected from the group consisting of hydrogen (H), methyl, ethyl, propyl, butyl, pentyl, and their isomers, in particular from the group consisting of hydrogen (H), methyl, ethyl, n-propyl, iso-propyl, n-butyl, iso-butyl, sec-butyl and tert-butyl, with the proviso that exactly two or exactly three or exactly four or exactly five of the radicals R^{B}, R^{C}, R^{D}, R^{E} and R^{F} are unequal hydrogen (H), advantageously exactly two or exactly five of the radicals R^{B}, R^{C}, R^{D}, R^{E} and R^{F} are unequal hydrogen (H).

Then the pi-donor ligand L_{C} is, for example, an anion selected from the group consisting of Me₂Cp⁻, Me(Et)Cp⁻, Et₂Cp⁻, Me(iPr)Cp⁻, Et(iPr)Cp⁻, iPr₂Cp⁻, Me(iBu)Cp⁻, Et(iBu)Cp⁻, iBu₂Cp⁻, Me(sBu)Cp⁻, Et(sBu)Cp⁻ and sBu₂Cp⁻. Alternatively, the pi-donor ligand L_{C} can be, for example, Me₄Cp⁻ or Me(Et)₂Cp⁻ or Et₂(iBu)Cp⁻ or Me₅Cp⁻ (Cp*).

According to a further advantageous embodiment of the here presented metal complex it is provided that the ligand L_{Z} is a monoanionic pi-donor ligand, wherein
i. the monoanionic pi-donor ligand L_{C} or the monoanionic pi-donor ligand L_{Z} is selected
or
ii. the monoanionic pi-donor ligand L_{C} and the monoanionic pi-donor ligand L_{Z} are independently of each other selected
from the group consisting of
   unsubstituted cyclopentadienide anion (C₅H₅⁻);
   monoalkyl-substituted cyclopentadienide anions according to the general formula R^{A}Cp⁻, wherein the radical R^{A} is selected from the group consisting of methyl, ethyl, propyl, butyl, pentyl, and their isomers, in particular from the group consisting of methyl, ethyl, n-propyl, iso-propyl, n-butyl, iso-butyl, sec-butyl and tert-butyl;
   polyalkyl-substituted cyclopentadienide anions according to the general formula R^{B}R^{C}R^{D}R^{E}R^{F}Cp⁻, wherein
   the radicals R^{B}, R^{C}, R^{D}, R^{E} and R^{F} are independently of each other selected from the group consisting of hydrogen (H), methyl, ethyl, propyl, butyl, pentyl, and their isomers, in particular from the group consisting of hydrogen (H), methyl, ethyl, n-propyl, iso-propyl, n-butyl, iso-butyl, sec-butyl and tert-butyl,
   with the proviso that at least two of the radicals R^{B}, R^{C}, R^{D}, R^{E} and R^{F} are unequal hydrogen (H).

In an alternative or complementary embodiment at least one of the radicals R¹ and R² of the triazenide anion L_{T} is selected from the group consisting of linear alkyl groups with 1 to 6 carbon atoms and branched alkyl groups with 3 to 6 carbon atoms.

According to a further embodiment of the here presented metal complex the radical R¹ and the radical R² of the triazenide anion L_{T} are independently of each other selected from the group consisting of methyl, ethyl, propyl, butyl, pentyl, and their isomers, in particular from the group consisting of methyl, ethyl, iso-propyl, iso-butyl, sec-butyl and tert-butyl.

If the ligand L_{Z} is a monoanionic pi-donor ligand, it can also be provided that
i. the monoanionic pi-donor ligand L_{C} or the monoanionic pi-donor ligand L_{Z} is selected
or
ii. the monoanionic pi-donor ligand L_{C} and the monoanionic pi-donor ligand L_{Z} are independently of each other selected
from the group consisting of polyalkyl-substituted cyclopentadienide anions according to the general formula R^{B}R^{C}R^{D}R^{E}R^{F}Cp⁻, wherein the radicals R^{B}, R^{C}, R^{D}, R^{E} and R^{F} are independently of each other selected from the group consisting of hydrogen (H) methyl, ethyl, propyl, butyl, pentyl, and their isomers, in particular from the group consisting of hydrogen (H), methyl, ethyl, n-propyl, iso-propyl, n-butyl, iso-butyl, sec-butyl and tert-butyl,
with the proviso that at least two of the radicals R^{B}, R^{C}, R^{D}, R^{E} and RF, which are unequal hydrogen (H), are identical.

Then the pi-donor ligand L_{C} and/or the pi-donor ligand L_{Z} is, for example, selected from the group consisting of Me₄Cp⁻, Me(Et)₂Cp⁻, Et₂Cp⁻, Et₂(iBu)Cp⁻ and Me₅Cp⁻ (Cp*).

Moreover, it can be provided that
i. the monoanionic pi-donor ligand L_{C} or the monoanionic pi-donor ligand L_{Z} is selected
or
ii. the monoanionic pi-donor ligand L_{C} and the monoanionic pi-donor ligand L_{Z} are independently of each other selected
from the group consisting of polyalkyl-substituted cyclopentadienide anions according to the general formula R^{B}R^{C}R^{D}R^{E}R^{F}Cp⁻, wherein the radicals R^{B}, R^{C}, R^{D}, R^{E} and R^{F} are independently of each other selected from the group consisting of hydrogen (H), methyl, ethyl, propyl, butyl, pentyl, and their isomers, in particular from the group consisting of hydrogen (H), methyl, ethyl, n-propyl, iso-propyl, n-butyl, iso-butyl, sec-butyl and tert-butyl, with the proviso that exactly two or exactly three or exactly four or exactly five of the radicals R^{B}, R^{C}, R^{D}, R^{E} and R^{F} are unequal hydrogen (H), advantageously exactly two or exactly five of the radicals R^{B}, R^{C}, R^{D}, R^{E} and R^{F} are unequal hydrogen (H).

Then the pi-donor ligand L_{C} and/or the pi-donor ligand L_{Z} is, for example, selected from the group consisting of Me₂Cp⁻, Me(Et)Cp⁻, Et₂Cp⁻, Me(iPr)Cp⁻, Et(iPr)Cp⁻, iPr₂Cp⁻, Me(iBu)Cp⁻, Et(iBu)Cp⁻, iBu₂Cp⁻, Me(sBu)Cp⁻, Et(sBu)Cp⁻ and sBu₂Cp⁻. Alternatively, the pi-donor ligand L_{C} and/or the pi-donor ligand L_{Z} can be, for example, Me₄Cp⁻ or Me(Et)₂Cp⁻ or Et₂(iBu)Cp⁻ or Me₅Cp⁻ (Cp*).

In an even different variant of the metal complex described here it is provided that L_{Z} is a monoanionic pi-donor ligand, wherein the monoanionic pi-donor ligand L_{C} and the monoanionic pi-donor ligand L_{Z} are identical.

According to a further advantageous embodiment of the herein presented metal complex the ligand L_{Z} is a triazenide anion according to the general formula (R¹—N₃—R²)—, wherein at least one of the radicals R¹ and R² of the triazenide anion L_{Z} is selected from the group consisting of linear alkyl groups with 1 to 6 carbon atoms and branched alkyl groups with 3 to 6 carbon atoms.

Another advantageous embodiment provides that the ligand L_{Z} is a triazenide anion according to the general formula (R¹—N₃—R²)—, wherein the radical R¹ and the radical R² of the triazenide anion L_{Z} are independently of each other and independently of the triazenide anion L_{T} selected from the group consisting of methyl, ethyl, propyl, butyl, pentyl, and their isomers, in particular from the group consisting of methyl, ethyl, iso-propyl, iso-butyl, sec-butyl and tert-butyl.

In a further variant of the here presented metal complex L_{Z} is a triazenide anion according to the general formula (R¹—N₃—R²)—, wherein the triazenide anion L_{T} and the triazenide anion L_{Z} are identical.

According to an even different embodiment of the here presented metal complex it is provided that
i. the radical R¹ and the radical R² of the triazenide anion L_{T} are identical,
and/or
ii. L_{Z} is a triazenide anion according to the general formula (R¹—N₃—R²)—, wherein the radical R¹ and the radical R² of the triazenide anion L_{Z} are identical;

A still different advantageous embodiment of the metal complex described here provides that the metal central atom M is selected from the group consisting of Sc, Y, La, Ce, Nd, Eu, Er, Lu and Ti, and
A. the ligand L_{Z} is a monoanionic pi-donor ligand, wherein
   i. the monoanionic pi-donor ligand L_{C} or the monoanionic pi-donor ligand L_{Z} is selected
   or
   ii. the monoanionic pi-donor ligand L_{C} and the monoanionic pi-donor ligand L_{Z} are independently of each other selected
   from the group consisting of
      unsubstituted cyclopentadienide anion (C₅H₅⁻);
      monoalkyl-substituted cyclopentadienide anions according to the general formula R^{A}Cp⁻, wherein the radical R^{A} is selected from the group consisting of methyl, ethyl, n-propyl, iso-propyl, n-butyl, iso-butyl, sec-butyl and tert-butyl;
      polyalkyl-substituted cyclopentadienide anions according to the general formula R^{B}R^{C}R^{D}R^{E}R^{F}Cp⁻, wherein
      the radicals R^{B}, R^{C}, R^{D}, R^{E} and R^{F} are independently of each other selected from the group consisting of hydrogen (H), methyl, ethyl, n-propyl, iso-propyl, n-butyl, iso-butyl, sec-butyl and tert-butyl,
      with the proviso that at least two of the radicals R^{B}, R^{C}, R^{D}, R^{E} and RF, which are unequal hydrogen (H), are identical;
   and
   the radical R¹ and the radical R² of the triazenide anion L_{T} are independently of
   each other selected from the group consisting of methyl, ethyl, iso-propyl, iso-butyl, sec-butyl and tert-butyl;
or
B. the ligand L_{Z} is a triazenide anion according to the general formula (R¹—N₃—R²)⁻, wherein
   i. the radicals R¹ and R² of one of the two triazenide anions L_{T} and L_{Z} are independently of each other selected from the group consisting of methyl, ethyl, iso-propyl, iso-butyl, sec-butyl and tert-butyl,
   or
   ii. the radicals R¹ and R² of the triazenide anion L_{T} and the radicals R¹ and R² of the triazenide anion L_{Z} are each independently of each other selected from the group consisting of methyl, ethyl, iso-propyl, iso-butyl, sec-butyl and tert-butyl;
   and
   the monoanionic pi-donor ligand L_{C} is selected from the group consisting of
      unsubstituted cyclopentadienide anion (C₅H₅⁻);
      monoalkyl-substituted cyclopentadienide anions according to the general formula R^{A}Cp⁻, wherein
      the radical R^{A} is selected from the group consisting of methyl, ethyl, n-propyl, iso-propyl, n-butyl, iso-butyl, sec-butyl and tert-butyl;
      polyalkyl-substituted cyclopentadienide anions according to the general formula R^{B}R^{C}R^{D}R^{E}R^{F}Cp⁻, wherein
      the radicals R^{B}, R^{C}, R^{D}, R^{E} and R^{F} are independently of each other selected from the group consisting of hydrogen (H), methyl, ethyl, n-propyl, iso-propyl, n-butyl, iso-butyl, sec-butyl and tert-butyl,
      with the proviso that at least two of the radicals R^{B}, R^{C}, R^{D}, R^{E} and R^{F}, which are unequal hydrogen (H), are identical.

According to variant A. it may be provided, for example, that the pi-donor ligand L_{C} and/or the pi-donor ligand L_{Z} is selected from the group consisting of Cp⁻ (C₅H₅⁻), MeCp⁻ (MeC₅H₄⁻), EtCp⁻ (EtC₅H₄⁻), iPrCp⁻ (iPrC₅H₄⁻), iBuCp⁻ (iBuC₅H₄⁻), sBuCp⁻ (sBuC₅H₄⁻), tBuCp⁻ (tBuC₅H₄⁻), Et₂Cp⁻ (Et₂C₅H₃⁻) and Me₅Cp⁻ (Cp*, C₅Me₅⁻). And the triazenide ligand L_{T} may, for example, be selected from the group consisting of (Me-N₃-Me)⁻, (iPr-N₃-iPr)⁻, (iPr-N₃-tBu)⁻, (tBu-N₃-tBu)⁻ and (iBu-N₃-iBu)⁻.

According to variant B. the triazenide ligand L_{T} and/or the triazenide ligand L_{Z} may, for example, be selected from the group consisting of (Me-N₃-Me)⁻, (iPr-N₃-iPr)⁻, (iPr-N₃—(Bu)⁻, (tBu-N₃-tBu)⁻ and (iBu-N₃-iBu)⁻. And the monoanionic pi-donor ligand L_{C} is for example selected from the group consisting of Cp⁻ (C₅H₅⁻), MeCp⁻ (MeC₅H₄⁻), EtCp⁻ (EtC₅H₄⁻), iPrCp⁻ (iPrC₅H₄⁻), iBuCp⁻ (iBuC₅H₄⁻), sBuCp⁻ (sBuC₅H₄⁻), tBuCp⁻ (tBuC₅H₄⁻), Et₂Cp⁻ (Et₂C₅H₃⁻) and Me₅Cp⁻ (Cp*, C₅Me₅⁻).

According to a further embodiment of the metal complex described here the metal complex has the formula I.1 or the formula I.2 or the formula I.3 or the formula I.4 or the formula I.5 or the formula I.6 or the formula I.7 or the formula I.8 or the formula I.9 or the formula I.10 or the formula I.11:

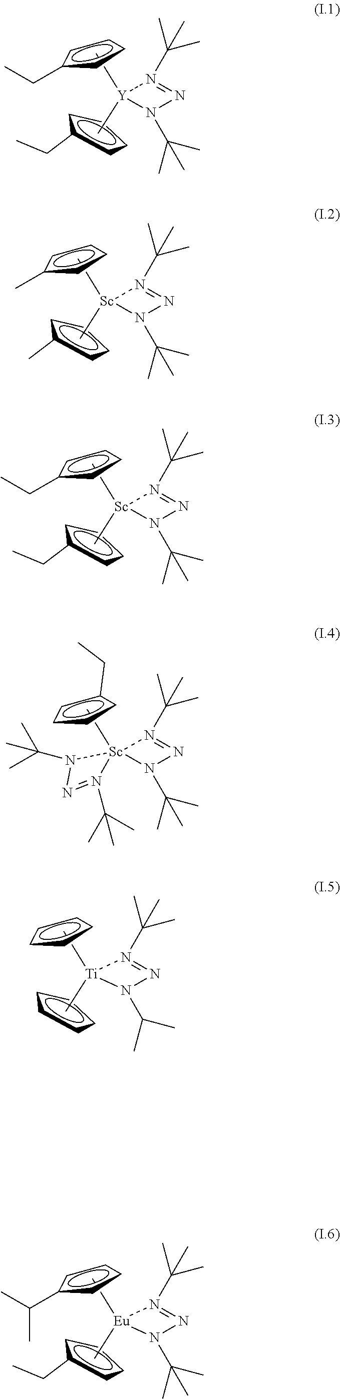

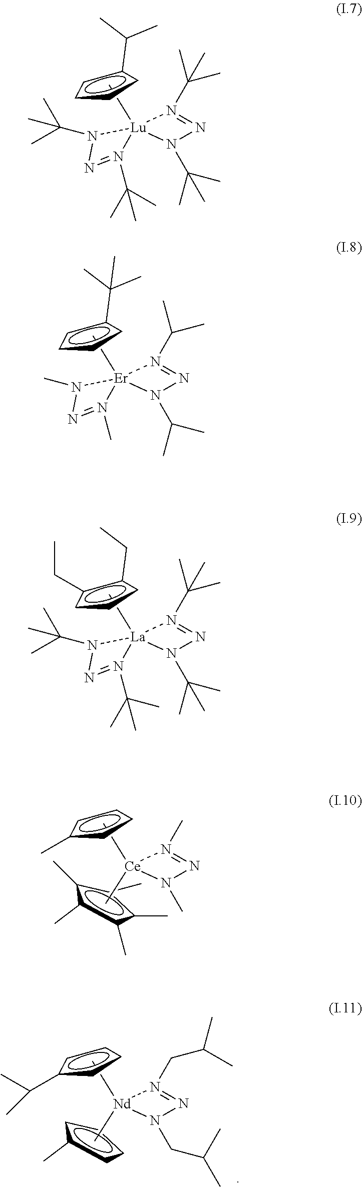

According to another advantageous embodiment of the metal complex described here the metal complex is vaporisable without decomposition or sublimable without decomposition.

This is particularly advantageous, especially since the incorporation rate of the respective metal M is increased due to the transition, without decomposition, of the metal complex into the gas phase. The incorporation rate of nitrogen is also increased. The produced layers are of high quality as to their purity, their composition and their morphology. Overall, by this property of the metal complex the (atomic) economical and ecological balance of the process is particularly positive influenced. For further details concerning the advantages of the transition, without decomposition, of a precursor compound into the gas phase, reference is made to the information in this regard provided above.

According to a further advantageous alternative or complementary variant a molecular weight of the metal complex is less than 600 g/mol, advantageously at most 595 g/mol, in particular less than 595 g/mol.

In comparison, two homoleptic Ln (III) triazenide complexes (Ln=La or Ce) described in WO 2019/115646 each have a molecular weight of more than 600 g/mol (approx. 608 g/mol).

The generally comparatively low molecular weight of the here described metal complex according to formula I, advantageously of at most 595 g/mol, in particular of less than 595 g/mol, advantageously facilitates an especially (energy) efficient transfer of the metal complex into the gas phase.

Metal complexes according to formula I, wherein M=Sc, Y or Ti, can have molecular weights of less than 550 g/mol or of less than 500 g/mol, for example in the range from 350 g/mol to 550 g/mol. Thus, in the case of the Y(III) compound, shown above, according to formula I.1, the molecular weight is between 400 g/mol and 450 g/mol, namely approx. 431 g/mol, and in the case of the Sc(III) complex, illustrated above, according to formula I.2, between 350 g/mol and 400 g/mol, namely approx. 360 g/mol.

In addition, the object is solved by a method for producing a layer which
i. consists of at least one metal M,
   wherein the at least one metal M is selected from the group consisting of scandium, yttrium, lanthanides and titanium,
or
ii. contains at least one metal M,
   wherein the at least one metal M is selected from the group consisting of scandium, yttrium, lanthanides and titanium,
on a surface of a substrate, in particular of a semiconductor substrate, using
   at least one metal complex according to the general formula [M(L_{C})(L_{T})(L_{Z})] (I)
   according to one or more of the embodiments described above,
or
   a solution comprising at least one metal complex according to the general formula [M(L_{C})(L_{T})(L_{Z})] (I) according to one or more of the embodiments described above and an aprotic non-polar solvent.

Thereby, the method comprises the following steps:
A. provision
   of the at least one metal complex according to one or more of the embodiments described above,
   or
   of the solution comprising at least one metal complex according to one or more of the embodiments described above and an aprotic non-polar solvent,
and
B. deposition of the layer which
   i. consists of the at least one metal M,
   or
   ii. contains the at least one metal M,
   on the surface of the substrate using the at least one metal complex provided in step A. as precursor compound.

The at least one metal complex of the type [M(L_{C})(L_{T})(L_{Z})] (I) described above to be provided in step A. or the solution to be provided, comprising at least one metal complex according to the general formula [M(L_{C})(L_{T})(L_{Z})] (I), are, due to their high purity (according to ¹H NMR spectroscopic examination) of at least 97%, advantageously of more than 97%, in particular of more than 98% or 99%, especially well suited as precursor compound or as solution containing a precursor compound for the production of a layer of high quality on a surface of a substrate. Thereby, the layer consists of at least one metal selected from the group consisting of scandium, yttrium, lanthanides, wherein the lanthanide is, for example, La, Ce, Nd, Eu, Er or Lu, and titanium. Also, for the production of a layer of high quality, containing at least one metal selected from the group consisting of scandium, yttrium, lanthanides, wherein the lanthanide is, for example, La, Ce, Nd, Eu, Er or Lu, and titanium, the aforementioned metal complexes according to the general formula I as well as solutions comprising at least one such metal complex are suitable.

In connection with the present invention, the term “high purity” and the term “highly pure” refer to a total content of impurities due to undesirable metals, undesirable semimetals, atmospheric oxygen and water of below 1 ppm, ideally of below 100 ppb. In the semiconductor industry, such a level of purity is referred to as electronic grade. Potential impurities due to volatile organic compounds, in particular due to organic solvents used as part of the synthesis, are not considered with this purity specification. As to this type of impurity, the purity of the metal complexes according to formula I is usually at least 97%, advantageously more than 97%, in particular more than 98% or 99%.

The deposition of the respective scandium layer, yttrium layer, lanthanide layer, wherein the lanthanide is, for example, La, Ce, Nd, Eu, Er or Lu, or titanium layer or of the layer containing at least one of the aforementioned metals can be carried out by means of a CVD process, for example by means of an MOCVD process, an MOVPE process or an ALD process.

As substrate corundum foils or thin metallic foils can be used, for example. The substrate can itself be part of a component and/or already be provided with a semiconductor layer, for example with a layer consisting of a III-V semiconductor such as gallium nitride (GaN).

In one embodiment of the method described here, the substrate is a wafer. The wafer may comprise silicon, silicon carbide, germanium, gallium nitride, gallium arsenide, indium phosphide, a glass, such as SiO₂, and/or a synthetic, such as silicone, or consist entirely of one or more of these materials. Besides, the wafer can exhibit one or more wafer layers, each with a surface. The production of a layer consisting of at least one metal selected from the group consisting of scandium, yttrium, lanthanides, wherein the lanthanide is, for example, La, Ce, Nd, Eu, Er or Lu, and titanium, or of a layer containing at least one metal selected from the group consisting of scandium, yttrium, lanthanides, wherein the lanthanide is, for example, La, Ce, Nd, Eu, Er or Lu, and titanium, may be provided for on the surface of one or more wafer layers. The layer containing at least one metal can be a Ln₂O₃ layer, for example also a layer containing a mixed oxide of two lanthanides or consisting of a mixed oxide of two lanthanides.

Besides, the object is solved by a substrate exhibiting on a surface at least one layer which
i. consists of at least one metal M,
   wherein the at least one metal M is selected from the group consisting of scandium,
   yttrium, lanthanides and titanium,
or
ii. contains at least one metal M,
   wherein the at least one metal M is selected from the group consisting of scandium, yttrium, lanthanides and titanium,
wherein the metal layer consisting of the at least one metal M, or the layer containing the at least one metal M, is produced using
   at least one metal complex according to the general formula [M(L_{C})(L_{T})(L_{Z}) (I)]
   according to one or more of the embodiments described above,
or
   a solution comprising at least one metal complex according to the general formula [M(L_{C})(L_{T})(L_{Z})] (I) according to one or more of the embodiments described above and an aprotic non-polar solvent.

The at least one metal complex of the type [M(L_{C})(L_{T})(L_{Z})] (I), described above, to be used or the solution to be used, comprising at least one metal complex according to the general formula [M(L_{C})(L_{T})(L_{Z})] (I), are, due to their high purity, especially well suited as precursor compound or as solution containing a precursor compound for the production of a layer of high quality on a surface of a substrate.

A definition of the term “high purity” is stated in connection with the method for producing a layer consisting of at least one metal M or a layer containing at least one metal M on a surface of a substrate.

The deposition of the respective scandium layer, yttrium layer, lanthanide layer, wherein the lanthanide is, for example, La, Ce, Nd, Eu, Er or Lu, or titanium layer or of the layer containing at least one of the aforementioned metals can be carried out by means of a CVD process, for example by means of an MOCVD process, an MOVPE process or an ALD process.

The substrate may be a corundum foil or a thin metallic foil, for example. It can itself be part of a component and/or already be provided with a semiconductor layer, for example with a layer consisting of a III-V semiconductor such as gallium nitride (GaN).

In one embodiment of the substrate described here, the substrate is a wafer. The wafer may comprise silicon, silicon carbide, germanium, gallium nitride, gallium arsenide, indium phosphide, a glass, such as SiO₂, and/or a synthetic, such as silicone, or consist entirely of one or more of these materials. Besides, the wafer can exhibit one or more wafer layers, each with a surface. The production of a layer consisting of at least one metal selected from the group consisting of scandium, yttrium, lanthanides, wherein the lanthanide is, for example, La, Ce, Nd, Eu, Er or Lu, and titanium, or of a layer containing at least one metal selected from the group consisting of scandium, yttrium, lanthanides, wherein the lanthanide is, for example, La, Ce, Nd, Eu, Er or Lu, and titanium, may be provided for on the surface of one or more wafer layers. The layer containing at least one metal can be a Ln₂O₃ layer, for example also a layer containing a mixed oxide of two lanthanides or consisting of a mixed oxide of two lanthanides.

Furthermore, the object is solved by a method for producing an electronic component, in particular an electronic semiconductor component, using
at least one metal complex according to the general formula [M(L_{C})(L_{T})(L_{Z})] (I) according to one or more of the embodiments described above,
or
a solution comprising at least one metal complex according to the general formula [M(L_{C})(L_{T})(L_{Z})] (I) according to one or more of the embodiments described above and an aprotic non-polar solvent.

Thereby, the method comprises the following steps:
A. provision
   of the at least one metal complex according to the general formula [M(L_{C})(L_{T})(L_{Z})] (I) according to one or more embodiments described above,
   or
   of the solution comprising at least one metal complex according to the general formula [M(L_{C})(L_{T})(L_{Z})] (I) according to one or more of the embodiments described above and an aprotic non-polar solvent,
B. deposition of a layer which
   i. consists of the at least one metal M,
   or
   ii. contains the at least one metal M,
   on a surface of a substrate,
and
C. completion of the electronic component, in particular the electronic semiconductor component.

The electronic component, in particular the electronic semiconductor component, is for example a detector, a photo element, a semiconductor diode, a laser, an electronic switching element, in particular a field effect transistor or a high-electron-mobility transistor or a fibre-optic emitter or a fibre-optic sensor.

The at least one metal complex of the type [M(L_{C})(L_{T})(L_{Z})] (I), described above, to be used or the solution to be used, comprising at least one metal complex according to the general formula [M(L_{C})(L_{T})(L_{Z})] (I), are, due to their high purity, especially well suited as precursor compound or as solution containing a precursor compound for the production of a layer of high quality on a surface of a substrate.

A definition of the term “high purity” is stated in connection with the method for producing a layer consisting of at least one metal M or a layer containing at least one metal M on a surface of a substrate.

The deposition of the respective scandium layer, yttrium layer, lanthanide layer, wherein the lanthanide is, for example, La, Ce, Nd, Eu, Er or Lu, or titanium layer or of the layer containing at least one of the aforementioned metals can be carried out by means of a CVD process, for example by means of an MOCVD process, an MOVPE process or an ALD process.

The substrate may be a corundum foil or a thin metallic foil, for example. It can itself be part of a component and/or already be provided with a semiconductor layer, for example with a layer consisting of a III-V semiconductor such as gallium nitride (GaN).

In one embodiment of the method described here, the substrate is a wafer. The wafer may comprise silicon, silicon carbide, germanium, gallium nitride, gallium arsenide, indium phosphide, a glass, such as SiO₂, and/or a synthetic, such as silicone, or consist entirely of one or more of these materials. Besides, the wafer can exhibit one or more wafer layers, each with a surface. The production of a layer consisting of at least one metal selected from the group consisting of scandium, yttrium, lanthanides, wherein the lanthanide is, for example, La, Ce, Nd, Eu, Er or Lu, and titanium, or of a layer containing at least one metal selected from the group consisting of scandium, yttrium, lanthanides, wherein the lanthanide is, for example, La, Ce, Nd, Eu, Er or Lu, and titanium, may be provided for on the surface of one or more wafer layers. The layer containing at least one metal can be a Ln₂O₃ layer, for example also a layer containing a mixed oxide of two lanthanides or consisting of a mixed oxide of two lanthanides.

Further features, details and advantages of the invention result from the wording of the claims and from the following description of embodiments and drawings. It show:

FIG. 1 a TGA curve and an SDTA curve (curve of a differential thermal analysis carried out simultaneously with the TGA measurement; synchronous differential thermal analysis) of the metal complex [(EtCp)₂Sc(dbt)], whereat dbt=di-tert-butyl-triazenide anion, prepared according to Example 3.1;

FIG. 2 a TGA curve and an SDTA curve of the metal complex [(EtCp)Sc(dbt)₂], whereat dbt=di-tert-butyl-triazenide anion, prepared according to Example 4; and

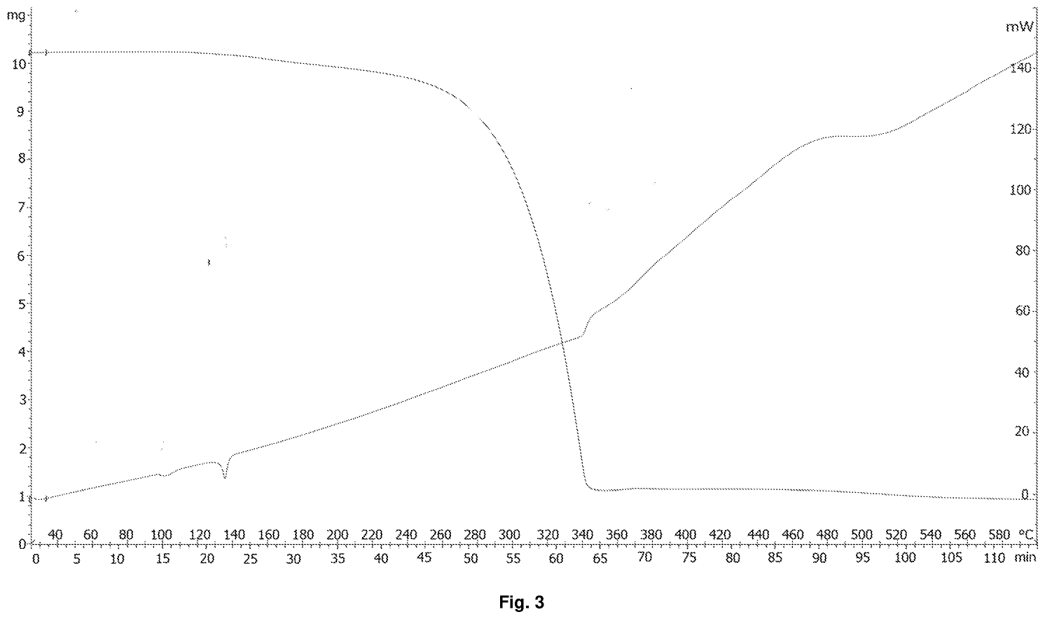

FIG. 3 a TGA curve and an SDTA curve of the pre-known complex [(MeCp)₂ScCl]₂.

The TGA curves shown in FIG. 1 and in FIG. 2 were recorded from two metal complexes according to the general formula I, whereat for both complexes it applies: M=Sc, L_{C}=EtCp⁻ and L_{T}=(tBu-N₃-tBu)⁻. For the first metal complex it applies, in addition, L_{Z}=L_{C}, for the second metal complex it applies L_{Z}=L_{T}.

In FIG. 3 a TGA curve of the pre-known precursor material [(MeCp)₂ScCl]₂ is shown for comparison purposes. This Sc(III) complex was prepared according to a procedure given in WO 2018/086730 A9.

On the x-axis the temperature in ° C. is plotted in each case—for both the TGA measurement and the SDTA measurement—whereat the relevant numerical values are indicated above the x-axis.

For the TGA measurement, the left y-axis, on which the initial weight in mg is plotted, is also important, as well as the second y-axis (from the left; not shown in FIG. 3), on which the remaining mass in % is plotted. On the right y-axis, relevant for the SDTA measurement, the heat flow difference in mW is plotted.

From the TGA curves presented in FIG. 1 and FIG. 2 it arises that both the Sc(III) complex [(EtCp)₂Sc(dbt)] and the Sc(III) complex [(EtCp)Sc(dbt)₂] are vaporisable, advantageously without decomposition, at low temperatures, namely in the range of 200° C. The low melting temperatures of these compounds are readable from the respective related SDTA curves: approx. 10° C. in the case of the complex [(EtCp)₂Sc(dbt)] and approx. 45° C. for the compound [(EtCp)Sc(dbt)₂]).

By contrast, from the TGA curve illustrated in FIG. 3 it arises that the pre-known Sc(III) precursor [(MeCp)₂ScCl]₂ unfavourably shows no vaporisation without decomposition. The melting temperature of this pre-known complex is approx. 160° C.

Due to the fact that the Sc(III) complexes [(EtCp)₂Sc(dbt)] and [(EtCp)Sc(dbt)₂] are producible in high purity, even on a commercial scale, and are vaporisable without decomposition—the latter even at relatively low temperatures in the range of 200° C.—they are predestined as precursor materials in processes of chemical vapour deposition (CVD processes), in particular for the production of scandium layers or scandium-containing layers, e.g. AlScN layers, of high quality on semiconductor substrates. This was confirmed, for example, by using the complex [(EtCp)₂Sc(dbt)] in an MOVPE process. Information in this regard is stated above.

### Procedures for the Synthesis of [(EtCp)₂Y(dbt)], [(MeCp)₂Sc(dbt)], [(EtCp)₂Sc(dbt)], [(EtCp)Sc(dbt)₂], [(Cp) 2Ti(pbt)], [(iPrCp)(EtCp)Eu(dbt)], [(iPrCp)Lu(dbt)₂], [(tBuCp)Er(dmt)(dpt)], [(Et₂Cp)La(dbt)₂], [(Cp*)(MeCp)Ce(dmt)], [(iPrCp)(MeCp)Nd(dibt)]

Thereby applies:
Cp=cyclopentadienide anion, C₅H₅⁻; MeCp=methylcyclopentadienide anion, MeC₅H₄⁻; EtCp=ethylcyclopentadienide anion, EtC₅H₄⁻; Et₂Cp=di-ethyl-cyclopentadienide anion, Et₂C₅H₃⁻; iPrCp=iso-propyl-cyclopentadienide anion, iPrC₅H₄⁻; tBuCp=tert-butylcyclopentadienide anion, (BuC₅H₄⁻; Cp*=1,2,3,4,5-pentamethylcyclopentadienide anion, C₅Me₅⁻; dmt=di-methyl-triazenide anion, (Me-N₃-Me)⁻; dpt=di-iso-propyl-triazenide anion, (iPr-N₃-iPr)⁻; pbt=iso-propyl-tert-butyl-triazenide anion, (iPr-N₃-tBu)⁻; dbt=di-tert-butyl-triazenide anion,
(tBu-N₃-tBu)⁻; dibt=di-iso-butyl-triazenide anion (iBu-N₃-iBu).

### Materials and Methods

All reactions were carried out under protective gas atmosphere by means of common Schlenk techniques. The applied starting materials and solvents had the purity degree p.a.

All nuclear magnetic resonance spectroscopic measurements were performed on an instrument of the type Bruker AV II 300. ¹H NMR and ¹³C NMR spectra were calibrated to the relevant residual proton signal of the solvent (C₆D₆) as internal standard: ¹H: 7.16 ppm(s); ¹³C: 128.0 ppm (tr). The chemical shifts are given in ppm and refer to the δ-scale. All signals are, in accordance with their splitting pattern, provided with the following abbreviations: s (singlet), t (triplet), q (quartet) or m (multiplet). The coupling between two nuclei A and B via n bonds is indicated by the coupling constant of the form ⁿJ_{AB} in Hertz (Hz).

The measurements of infrared spectra were generally carried out in substance on an Alpha ATR-IR spectrometer from Bruker. The absorption bands are given in wave number (cm⁻¹) and the intensity is described with the following abbreviations: w (weak), m (medium), s (strong). The spectra were always normalised to the band with the strongest intensity.

The thermogravimetric analyses were conducted at a TGA/DSC 3+ STAR system from Mettler Toledo. Thereby, with each TGA measurement a coupled SDTA measurement was carried out. The samples were measured in aluminium oxide, aluminium or sapphire crucibles, depending on the method and depending on the aggregation state, respectively. The sample was heated up to the final temperature with a defined heating rate each between 5 K/min and 25 K/min. The evaluation of the obtained spectra was performed using STARe software from Mettler Toledo.

### Example 1.1: Preparation of [(EtCp)₂Y(dbt)] Starting from YCl₃

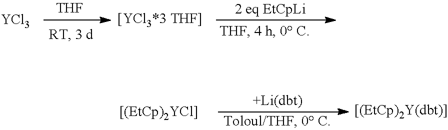

To 5.0 g YCl₃ (25.6 mmol) 150 mL THF were added at −60° C. and stirred for 3 days after warming to room temperature. To the resulting colourless suspension a solution of EtCpLi (56.3 mmol) in 50 mL THF was added dropwise at 0° C. within 4 hours. The reaction mixture turned completely clear when thawing to room temperature and was stirred for 16 hours at room temperature. The solvent was removed under vacuum. To the obtained residue 50 mL toluene were added and the suspension thus obtained was filtered. The filter cake was washed three times with 20 mL toluene each. The filtrate was diluted with 50 mL toluene and cooled to 0° C. Afterwards, 4.2 g Li(dbt) (25.6 mmol) were added in portions. The reaction mixture was heated to room temperature first and subsequently heated to boiling point for 3 hours. The obtained suspension was filtered. The solvent of the filtrate was removed under vacuum and the crude product was distilled under vacuum at 180° C. The product was obtained as a colourless oil, which solidified slowly to a colourless solid at room temperature. Yield: 75% (6.0 g; 19.3 mmol).

### Example 1.2: Preparation of [(EtCp)₂Y(Dbt)] Starting from [(EtCp)₂YCl]

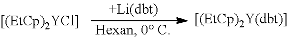

To 90.5 g (EtCp)₂YCl (291 mmol) in 600 mL n-hexane 47.5 g Li(dbt) (291 mmol) were added in portions at 0° C. over a period of 2 hours. The reaction mixture was stirred for 2 hours at 0° C. and subsequently for 16 h at room temperature. Afterwards, the reaction mixture was then heated to boiling point for 3 hours. The obtained suspension was filtered and the filter cake was washed three times with 50 mL n-hexane each. The solvent of the filtrate was removed under vacuum and the crude product was distilled under vacuum at 180° C. The product was obtained as a colourless oil, which solidified slowly at room temperature. Yield: 78% (98 g; 227 mmol).

Melting temperature: approx. 40° C.; ¹H NMR (300 MHZ; C₆D₆): δ=1.14 (t, ³J_{HH}=7.6H, 6H, CH₂CH₃), 1.20 (s, 18H, C(CH₃)₃), 2.45 (q, ³J_{HH}=7.6H, 4H, CH₂CH₃), 5.96 (m, 4H, CH_{arom.}), 6.02 (m, 4H, CH_{arom.}) ppm; ¹³C NMR (75 MHZ; C₆D₆): δ=16.4 (s, 2C, CH₂CH₃), 23.3 (s, 2C, CH₂CH₃), 30.2 (s, 6C, C(CH₃)₃), 56.8 (s, 1C, C(CH₃)₃), 56.9 (s, 1C, C(CH₃)₃), 110.2 (s, 1C, CH_{arom.}), 110.2 (s, 1C, CH_{arom.}), 110.7 (s, 1C CH_{arom.}), 110.7 (s, 1C, CH_{arom.}), 130.3 (s, 1C, C_{arom. quaternary}) ppm; IR (substance): \tilde{v}=3064 (w), 2965 (m), 2928 (w), 2897 (w), 2867 (w), 1471 (w), 1459 (w), 1382 (w), 1357 (m), 1318 (w), 1278 (s), 1248 (m), 1202 (s), 1043 (w), 1027 (m), 911 (w), 854 (m), 764 (s), 665 (w), 619 (s), 554 (w), 487 (w), 465 (w), 426 (w) cm-1.

### Example 2: Preparation of [(MeCp)₂Sc(dbt)]

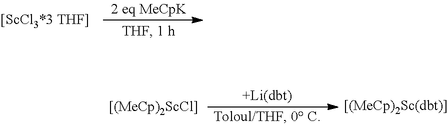

7.35 g [ScCl₃*3 THF] (20 mmol) were suspended in 50 mL THF. A solution of MeCpK (40 mmol) in 100 mL THF was added dropwise at room temperature within 1 hour. The reaction mixture was subsequently stirred for 16 hours at room temperature. The solvent was removed under vacuum and 50 mL toluene were added to the residue. The obtained suspension was filtered and the filter cake was washed three times with 20 mL toluene each. The filtrate was concentrated to a volume of approx. 30 mL and cooled to 0° C. Subsequently, 3.2 g Li(dbt) (20 mmol) were added in portions. After thawing 5 mL THF were added and the reaction mixture was stirred for 16 hours at room temperature. The obtained suspension was filtered, the solvent of the filtrate was removed under vacuum and the crude product was distilled under vacuum at 150° C. The product was obtained as a yellowish solid. Yield: 66% (5 g; 13.3 mmol).

Melting temperature: approx. 80° C. (estimated); ¹H NMR (300 MHZ; C₆D₆): δ=1.23 (s, 18H, C(CH₃)₃), 1.98 (s, 6H, cp-CH₃), 5.82 (m, 4H, CH_{arom.}), 6.89 (m, 4H, CH_{arom.}) ppm; ¹³C NMR (75 MHZ; C₆D₆): δ=15.7 (s, 2C, cp-CH₃), 30.4 (s, 6C, C(CH₃)₃), 57.3 (s, 2C, C(CH₃)₃), 110.3 (s, 2C, CH_{arom.}), 113.5 (s, 2C, CH_{arom.}), 121.4 (s, 1C, C_{arom. quaternary}) ppm; IR (substance): ˜=2965 (m), 2925 (w), 2898 (w), 2864 (w), 1469 (w), 1454 (w), 1383 (w), 1354 (m), 1283 (s), 1243 (m), 1201 (s), 1047 (m), 932 (w), 842 (m), 773 (s), 618 (s), 555 (w), 493 (m), 469 (m), 436 (w), 425 (w) cm-1.

### Note to Example 2

The synthesis of [(MeCp)₂Sc(dbt)] can be carried out-analogously to Example 1.2—Starting from [(MeCp)₂ScCl].

### Example 3.1: Preparation of [(EtCp)₂Sc(dbt)] Starting from [ScCl₃*3 THF]

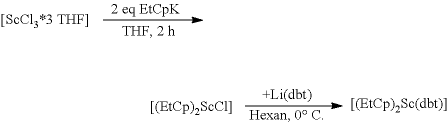

206.6 g [ScCl₃*3 THF] (562 mmol) were added as a solid in portions within 3 hours to a solution of EtCpK (1.12 mol) in 900 mL THF at 0° C. The reaction mixture was subsequently stirred for 2 hours at room temperature and thereupon heated to boiling point for 5 hours. The solvent was removed under vacuum and 500 mL n-hexane were added to the residue. The obtained suspension was filtered hotly and the residue was washed three times with 100 mL n-hexane each. The filtrate was concentrated to a volume of approx. 250 mL and stored at 0° C. overnight. The crystalline [(EtCp)₂ScCl] was subsequently separated from the mother liquor by decantation and the residue was dried under vacuum (yield: 75%; 127 g; 477 mmol). By further crystallisation from the mother liquor the yield of [(EtCp)₂ScCl] could be further increased.

73 g [(EtCp)₂ScCl] (273 mmol) were dissolved in 500 mL n-hexane in a 1 L flask. Afterwards, 44.6 g Li(dbt) (273 mmol) were added in portions at 0° C. After thawing it was stirred for 16 hours at room temperature. The obtained suspension was heated to boiling point for 3 hours and subsequently filtered hotly. The solvent of the filtrate was removed by distillation. [(EtCp)₂Sc(dbt)] was obtained by distillation of the residue (under dynamic vacuum, i.e. at approx. 1*10-3 mbar, at 155° C.) in the form of a yellow oil. Yield: 73% (80 g; 201 mmol).

### Example 3.2: Preparation of [(EtCp)₂Sc(Dbt)] Starting from [(EtCp)₂ScCl]

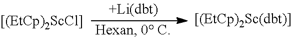

To 70 g [(EtCp)₂ScCl] (262 mmol) in 600 mL n-hexane 42.8 g Li(dbt) (262 mmol) were added in portions over a period of 2 hours at 0° C. The reaction mixture was stirred for 2 hours at 0° C. and subsequently for 16 h at room temperature. Afterwards, the reaction mixture was heated to boiling point for 3 hours. The obtained suspension was filtered and the filter cake was washed three times with 50 mL n-hexane each. The solvent of the filtrate was removed under vacuum. [(EtCp)₂Sc(dbt)] was obtained by distillation of the residue (under dynamic vacuum, i.e. at approx. 1*10-3 mbar, at 155° C.) in the form of a yellow oil. Yield: 81% (82 g; 212 mmol).

Melting temperature: approx. 10° C.; ¹H NMR (300 MHZ; C₆D₆): δ=1.13 (t, ³J_{HH}=7.6H, 6H, CH₂CH₃), 1.24 (s, 18H, C(CH₃)₃), 2.37 (q, ³J_{HH}=7.6H, 4H, CH₂CH₃), 5.89 (m, 8H, CH_{arom.}) ppm; 13C NMR (75 MHZ; C₆D₆): δ=16.4 (s, 2C, CH₂CH₃), 23.8 (s, 2C, CH₂CH₃), 30.4 (s, 6C, C(CH₃)₃), 57.4 (s, 1C, C(CH₃)₃), 110.4 (s, 4C, CH_{arom.}), 112.1 (s, 4C, CH_{arom.}), 128.6 (s, 2C, C_{arom, quaternary}) ppm.

### Example 4: Preparation of [(EtCp)Sc(dbt)₂] Starting from [ScCl₃*3 THF]

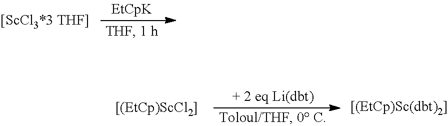

7.35 g [ScCl₃*3 THF] (20 mmol) were suspended in 50 mL THF. A solution of EtCpK (20 mmol) in 100 mL THF was added dropwise at room temperature within 1 hour. The reaction mixture was subsequently stirred for 16 hours at room temperature. The solvent was removed under vacuum and 50 mL toluene were added to the residue. The obtained suspension was filtered and the filter cake was washed three times with 20 mL toluene each. The filtrate was concentrated to a volume of approx. 30 mL and cooled to 0° C. Subsequently, 6.4 g Li(dbt) (20 mmol) were added in portions. After thawing 5 mL THF were added and the reaction mixture was stirred for 16 hours at room temperature. The obtained suspension was filtered, the solvent of the filtrate was removed under vacuum and the crude product was distilled under vacuum at 150° C. The product was obtained as a yellowish solid. Yield: 73% (6.6 g; 14.6 mmol).

Melting temperature: approx. 45° C.; ¹H NMR (300 MHZ; C₆D₆): δ=1.18 (t, ³J_{HH}=7.6H, 3H, CH₃), 1.31 (s, 36H, NC(CH₃)₃), 2.55 (q, ³J_{HH}=7.6 Hz, 2H, CH₂), 6.28 (s, 4H, CpH) ppm.

### Example 5: Preparation of [Cp₂Ti(pbt)] Starting from [Cp₂TiCl]

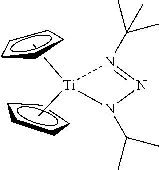

To 10.68 g [Cp₂TiCl] (50 mmol) in 150 mL n-hexane 7.46 g Li(pbt) (50 mmol) is added in portions at 0° C. over a period of 2 hours. The reaction mixture is stirred for 2 hours at 0° C. and thereafter for 16 h at room temperature. Subsequently, the reaction mixture is heated to boiling point for 3 hours. The obtained suspension is filtered and the filter cake is washed three times with 50 mL n-hexane each. The solvent of the filtrate is removed under vacuum. [(Cp) 2Ti(pbt)] is obtained by distillation of the residue. From the successful synthesis according to Example 1.2 and according to Example 3.2 the conclusion is drawn that a reaction of [Cp₂TiCl] with Li(pbt)—analogous to Example 1.2 and Example 3.2—results in the desired target compound [(Cp) 2Ti(pbt)].

According to Example 1.2 the compound [(EtCp)₂Y(dbt)] was obtained starting from [(EtCp)₂YCl] and Li(dbt). Analogously, according to Example 3.2 the complex [(EtCp)₂Sc(dbt)] was obtained starting from [(EtCp)₂ScCl] and Li(dbt), in fact in comparable yield and purity as the complex [(EtCp)₂Y(dbt)].

If, instead of [(EtCp)₂YCl] or [(EtCp)₂ScCl], the titanium (III) complex [Cp₂TiCl] is—analogously to Example 1.2 or Example 3.2—reacted with Li(pbt) [(Cp) 2Ti(pbt)] is obtained. Because Ti³⁺ complexes, Y³⁺ complexes and Sc³⁺ complexes behave chemically analogously.

Yield and purity of [(Cp)₂Ti(pbt)] that are achieved according to this example are similar or identical to those having been obtained by means of the syntheses for [(EtCp)₂Y(dbt)] (Example 1.2) and for [(EtCp)₂Sc(dbt)] (Example 3.2) which are described above.

### Example 6: Preparation of [(iPrCp)(EtCp)Eu(dbt)] Starting from [(iPrCp)(EtCp)EuCl]

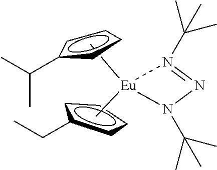

To 19.4 g [(iPrCp)(EtCp)EuCl] (50 mmol) in 150 mL n-hexane 8.16 g Li(dbt) (50 mmol) are added in portions at 0° C. over a period of 2 hours. The reaction mixture is stirred for 2 hours at 0° C. and thereafter for 16 hours at room temperature. Afterwards, the reaction mixture is heated to boiling point for 3 hours. The obtained suspension is filtered and the filter cake is washed three times with 50 mL n-hexane each. The solvent of the filtrate is removed under vacuum. [(iPrCp)(EtCp)Eu(dbt)] is obtained by distillation of the residue.

From the successful synthesis according to Example 1.2 and according to Example 3.2, the conclusion is drawn that a reaction of [(iPrCp)(EtCp)EuCl] with Li(pbt)—analogous to Example 1.2 and Example 3.2—results in the desired target compound [(iPrCp)(EtCp)Eu(dbt)].

According to Example 1.2 the compound [(EtCp)₂Y(dbt)] was obtained starting from [(EtCp)₂YCl] and Li(dbt). Analogously, according to Example 3.2 the complex [(EtCp)₂Sc(dbt)] was obtained starting from [(EtCp)₂ScCl] and Li(dbt), in fact in comparable yield and purity as the complex [(EtCp)₂Y(dbt)].

If, instead of [(EtCp)₂YCl] or [(EtCp)₂ScCl], the europium (III) complex [(iPrCp)(EtCp)EuCl] is—analogously to Example 1.2 or Example 3.2—reacted with Li(pbt) [(iPrCp)(EtCp)Eu(dbt)] is obtained. Because lanthanide (III) complexes, such as the Eu³⁺ complex intended here as starting material, behave chemically analogously to Y³⁺ complexes and Sc³⁺ complexes.

Yield and purity of [(iPrCp)(EtCp)Eu(dbt)] that are achieved according to this example are similar or identical to those having been obtained by means of the syntheses for [(EtCp)₂Y(dbt)] (Example 1.2) and for [(EtCp)₂Sc(dbt)] (Example 3.2) which are described above.

### Example 7: Preparation of [(iPrCp)Lu(dbt)₂] Starting from [(iPrCp)LuCl₂]

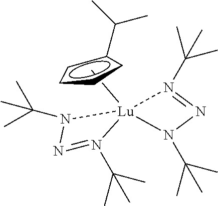

To 17.65 g [(iPrCp)LuCl₂] (50 mmol) in 150 mL n-hexane 16.32 g Li(dbt) (100 mmol) are added in portions at 0° C. over a period of 2 hours. The reaction mixture is stirred for 2 hours at 0° C. and subsequently for 16 hours at room temperature. Afterwards, the reaction mixture is heated to boiling point for 3 hours. The obtained suspension is filtered and the filter cake is washed three times with 50 mL n-hexane each. The solvent of the filtrate is removed under vacuum. [(iPrCp)Lu(dbt)₂] is obtained by distillation of the residue.

From the successful synthesis according to Example 1.2 and according to Example 3.2, the conclusion is drawn that a reaction of iso-propyl-cyclopentadienyl-lutetium dichloride [(iPrCp)LuCl₂] with Li(pbt)—analogous to Example 1.2 and Example 3.2, wherein, however, a molar ratio [(iPrCp)LuCl₂]:Li(pbt) is 1:2—results in the desired target compound [(iPrCp)Lu(dbt)_{2].}

According to Example 4 the compound [(EtCp)₂Y(dbt)] was obtained starting from [(EtCp)₂YCl] and Li(dbt), wherein a molar ratio of the starting materials was 1:1. Analogously, according to Example 3.2 the complex [(EtCp)₂Sc(dbt)] was obtained starting from [(EtCp)₂ScCl] and Li(dbt), in fact in comparable yield and purity as the complex [(EtCp)₂Y(dbt)].

If, instead of [(EtCp)₂YCl] or [(EtCp)₂ScCl], the lutetium (III) complex [(iPrCp)LuCl₂] is-analogously to Example 1.2 or Example 3.2, wherein, however, a molar ratio [(iPrCp)LuCl₂]:Li(pbt) is 1:2—reacted with Li(pbt), [(iPrCp)Lu(dbt)₂] is obtained. Because lanthanide (III) complexes, such as the Lu³⁺ complex intended here as starting material, behave chemically analogously to Y³⁺ complexes and Sc³⁺ complexes.

Yield and purity of [(iPrCp)Lu(dbt)₂] that are achieved according to this example are similar or identical to those having been obtained by means of the syntheses for [(EtCp)₂Y(dbt)] (Example 1.2) and for [(EtCp)₂Sc(dbt)] (Example 3.2) which are described above.

### Example 8: Preparation of [(tBuCp)Er(dmt)(dpt)] Starting from [(tBuCp)ErCl₂]

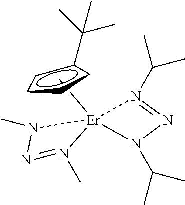

To 17.97 g [(tBuCp)ErCl₂] (50 mmol) in 150 mL n-hexane 3.95 g Li(dmt) (50 mmol) are added in portions at 0° C. over a period of 2 hours. Subsequently, 6.76 g Li(dpt) (50 mmol) are added in portions at 0° C. over a period of 2 hours. The reaction mixture is stirred for 2 hours at 0° C. and thereafter for 16 hours at room temperature. Afterwards, the reaction mixture is heated to boiling point for 3 hours. The obtained suspension is filtered and the filter cake is washed three times with 50 mL n-hexane each. The solvent of the filtrate is removed under vacuum. [(tBuCp)Er(dmt)(dpt)] is obtained by distillation of the residue.

From the successful synthesis according to Example 1.2 and according to Example 3.2, the conclusion is drawn that a reaction of tert-butyl-cyclopentadienyl-erbium dichloride [(tBuCp)ErCl₂] with the lithium salts Li(dmt) and Li(dpt)—analogous to Example 1.2 and Example 3.2, wherein, however, a molar ratio [(tBuCp)ErCl₂]:lithium salts is 1:2,—results in the desired target compound [(tBuCp)Er(dmt)(dpt)].

According to Example 1.2 the compound [(EtCp)₂Y(dbt)] was obtained starting from [(EtCp)₂YCl] and Li(dbt), wherein a molar ratio of the starting materials was 1:1. Analogously, according to Example 3.2 the complex [(EtCp)₂Sc(dbt)] was obtained starting from [(EtCp)₂ScCl] and Li(dbt), in fact in comparable yield and purity as the complex [(EtCp)₂Y(dbt)].

If, instead of [(EtCp)₂YCl] or [(EtCp)₂ScCl], the erbium (III) complex [(tBuCp)ErCl₂] is-analogously to Example 1.2 or Example 3.2, wherein, however, a molar ratio [(tBuCp)ErCl₂]:lithium salts is 1:2-reacted with Li(dmt) and Li(dpt), [(tBuCp)Er(dmt)(dpt)] is obtained. Because lanthanide (III) complexes, such as the Er³⁺ complex intended here as starting material, behave chemically analogously to Y³⁺ complexes and Sc³⁺ complexes.

Yield and purity of [(tBuCp)Er(dmt)(dpt)] that are achieved according to this example are similar or identical to those having been obtained by means of the syntheses for [(EtCp)₂Y(dbt)] (Example 1.2) and for [(EtCp)₂Sc(dbt)] (Example 3.2) which are described above.

### Example 9: Preparation of [(Et₂Cp)La(dbt)₂] Starting from [(Et₂Cp)LaCl₂]

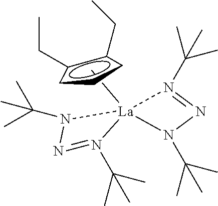

To 16.55 g [(Et₂Cp)LaCl₂] (50 mmol) in 200 mL n-hexane 16.32 g Li(dbt) (100 mmol) are added in portions at 0° C. over a period of 2 hours. The reaction mixture is stirred for 2 hours at 0° C. and subsequently for 16 hours at room temperature. Afterwards, the reaction mixture is heated to boiling point for 3 hours. The obtained suspension is filtered and the filter cake is washed three times with 50 mL n-hexane each. The solvent of the filtrate is removed under vacuum. [(Et₂Cp)La(dbt)₂] is obtained by distillation of the residue.

From the successful synthesis according to Example 1.2 and according to Example 3.2, the conclusion is drawn that a reaction of di-ethyl-cyclopentadienyl lanthanum dichloride [(Et₂Cp)LaCl₂] with the lithium salts Li(dbt)—analogous to Example 1.2 and Example 3.2, wherein, however, a molar ratio [(Et₂Cp)LaCl₂]:lithium salts is 1:2,—results in the desired target compound [(Et₂Cp)La(dbt)_{2].}

According to Example 1.2 the compound [(EtCp)₂Y(dbt)] was obtained starting from [(EtCp)₂YCl] and Li(dbt), wherein a molar ratio of the starting materials was 1:1. Analogously, according to Example 3.2 the complex [(EtCp)₂Sc(dbt)] was obtained starting from [(EtCp)₂ScCl] and Li(dbt), in fact in comparable yield and purity as the complex [(EtCp)₂Y(dbt)].

If, instead of [(EtCp)₂YCl] or [(EtCp)₂ScCl], the lanthanum (III) complex [(Et₂Cp)LaCl₂] is—analogously to Example 1.2 or Example 3.2, wherein, however, a molar ratio [(Et₂Cp)LaCl₂]:lithium salts is 1:2-reacted with Li(dbt), [(Et₂Cp)La(dbt)₂] is obtained. Because lanthanide (III) complexes, such as the La³⁺ complex intended here as starting material, behave chemically analogously to Y³⁺ complexes and Sc³⁺ complexes.

Yield and purity of [(Et₂Cp)La(dbt)₂] that are achieved according to this example are similar or identical to those having been obtained by means of the syntheses for [(EtCp)₂Y(dbt)] (Example 1.2) and for [(EtCp)₂Sc(dbt)] (Example 3.2) which are described above.

### Example 10: Preparation of [(Cp*)(MeCp)Ce(dmt)] Starting from [(Cp*)(MeCp)CeCl]

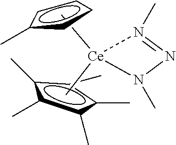

To 19.5 g [(Cp*)(MeCp)CeCl] (50 mmol) in 200 mL n-hexane 3.95 g Li(dmt) (50 mmol) are added in portions at 0° C. over a period of 2 hours. The reaction mixture is stirred for 2 hours at 0° C. and subsequently for 16 hours at room temperature. Afterwards, the reaction mixture is heated to boiling point for 3 hours. The obtained suspension is filtered and the filter cake is washed three times with 50 mL n-hexane each. The solvent of the filtrate is removed under vacuum. [(Cp*)(MeCp)Ce(dmt)] is obtained by distillation of the residue.

From the successful synthesis according to Example 1.2 and according to Example 3.2, the conclusion is drawn that a reaction of [(Cp*)(MeCp)CeCl] with Li(dmt)—analogous to Example 1.2 and Example 3.2—results in the desired target compound [(Cp*)(MeCp)Ce(dmt)].

According to Example 1.2 the compound [(EtCp)₂Y(dbt)] was obtained starting from [(EtCp)₂YCl] and Li(dbt). Analogously, according to Example 3.2 the complex [(EtCp)₂Sc(dbt)] was obtained starting from [(EtCp)₂ScCl] and Li(dbt), in fact in comparable yield and purity as the complex [(EtCp)₂Y(dbt)].

If, instead of [(EtCp)₂YCl] or [(EtCp)₂ScCl], the cerium (III) complex [(Cp*)(MeCp)CeCl] is—analogously to Example 1.2 or Example 3.2—reacted with Li(dmt)

[(Cp*)(MeCp)Ce(dmt)] is obtained. Because lanthanide (III) complexes, such as the Ce³⁺ complex intended here as starting material, behave chemically analogously to Y³⁺ complexes and Sc³⁺ complexes.

Yield and purity of [(Cp*)(MeCp)Ce(dmt)] that are achieved according to this example are similar or identical to those having been obtained by means of the syntheses for [(EtCp)₂Y(dbt)] (Example 1.2) and for [(EtCp)₂Sc(dbt)] (Example 3.2) which are described above.

### Example 11: Preparation of [(iPrCp)(MeCp)Nd(dibt)] Starting from [(iPrCp)(MeCp)NdCl]

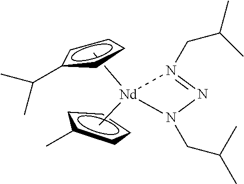

To 18.3 g [(iPrCp)(MeCp)NdCl] (50 mmol) in 200 mL n-hexane 8.16 g Li(dibt) (50 mmol) are added in portions at 0° C. over a period of 2 hours. The reaction mixture is stirred for 2 hours at 0° C. and subsequently for 16 hours at room temperature. Afterwards, the reaction mixture is heated to boiling point for 3 hours. The obtained suspension is filtered and the filter cake is washed three times with 50 mL n-hexane each. The solvent of the filtrate is removed under vacuum. [(iPrCp)(MeCp)Nd(dibt)] is obtained by distillation of the residue.

From the successful synthesis according to Example 1.2 and according to Example 3.2, the conclusion is drawn that a reaction of [(iPrCp)(MeCp)NdCl] with Li(dibt)—analogous to Example 1.2 and Example 3.2—results in the desired target compound [(iPrCp)(MeCp)Nd(dibt)].

According to Example 1.2 the compound [(EtCp)₂Y(dbt)] was obtained starting from [(EtCp)₂YCl] and Li(dbt). Analogously, according to Example 3.2 the complex [(EtCp)₂Sc(dbt)] was obtained starting from [(EtCp)₂ScCl] and Li(dbt), in fact in comparable yield and purity as the complex [(EtCp)₂Y(dbt)].

If, instead of [(EtCp)₂YCl] or [(EtCp)₂ScCl], the neodymium (III) complex [(iPrCp)(MeCp)NdCl] is—analogously to Example 1.2 or Example 3.2—reacted with Li(dibt) [(iPrCp)(MeCp)Nd(dibt)] is obtained. Because lanthanide (III) complexes, such as the Nd³⁺ complex intended here as starting material, behave chemically analogously to Y³⁺ complexes and Sc³⁺ complexes.

Yield and purity of [(iPrCp)(MeCp)Nd(dibt)] that are achieved according to this example are similar or identical to those having been obtained by means of the syntheses for [(EtCp)₂Y(dbt)] (Example 1.2) and for [(EtCp)₂Sc(dbt)] (Example 3.2) which are described above.

The invention is not limited to one of the embodiments described above, but modifiable in manifold ways.

It can be seen that the invention relates to metal complexes according to the formula [M(L_{C})(L_{T})(L_{Z})]. Thereby applies: M=scandium, yttrium, lanthanide or titanium; L_{C}=unsubstituted cyclopentadienide anion, monoalkyl-substituted or polyalkyl-substituted cyclopentadienide anion; L_{T}=triazenide anion (R¹—N₃—R²)—, wherein R¹ and R² are independently of each another a linear alkyl group with 1 to 10 carbon atoms or a branched alkyl group with 3 to 10 carbon atoms; L_{Z} is a) independently of L_{C} selected from the group mentioned for L_{C}, or b) independently of L_{T} selected from the group mentioned for L_{T}.

Subject matter of the invention is, in addition, the use of at least one such metal complex for producing a layer consisting of at least one metal M or containing at least one metal M on a surface of a substrate as well as for producing an electronic component. Moreover, the invention concerns a substrate exhibiting on a surface a layer consisting of at least one metal M or containing at least one metal M and produced using such a metal complex.

The here presented metal complexes according to the general formula [M(L_{C})(L_{T})(L_{Z})] (I) are producible highly pure in a straightforward manner in good to very good yields, even on an industrial scale. It is surprising and advantageous that these compounds exist solvent-free after their isolation and purification by means of distillation or sublimation. Particularly advantageous is that the heteroleptic, variable complex design, which provides for at least one ligand with a nitrogen-based, carbon-free skeleton (triazenide ligand), allows the provision of a variety of different, particularly tailor-made and application-specific optimised, respectively, metal complexes. Thereby the synthesis protocol described herein can advantageously, as a rule, be applied without significant alterations for producing a, particularly tailor-made for a specific process of chemical vapour deposition, compound of the type [M(L_{C})(L_{T})(L_{Z})] (I).

A further important advantage of the here described metal complexes of the type [M(L_{C})(L_{T})(L_{Z})] (I) is that they meet all requirements placed on precursor materials for chemical vapour deposition processes (CVD processes), for example MOCVD processes, MOVPE processes and ALD processes, and are thus predestined, in particular, for the use in processes of this type. The complex design of the compounds according to formula I does not only promote the incorporation of desired elements in a favourable way, namely of the respective metal M and of nitrogen, into the layer to be produced, but also leads to a reduction of the incorporation of undesired elements, such as carbon. The use of these complexes can advantageously take place at ideal process temperatures, so that metal layers and metal-containing layers of high quality can be produced. The produced layers are of high quality as to their purity, their composition and their morphology. Overall, from an (atomic) economical and ecological point of view the use of complexes of the here presented type in chemical vapour deposition processes is particularly advantageous.

All features and advantages resulting from the claims, the description and the figures, including constructional details, spatial arrangements and process steps, can be essential to the invention both separately and in a wide variety of combinations.

1. Metal complex according to the general formula 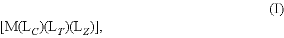
wherein
i. M is a metal central atom selected from the group consisting of scandium (Sc), yttrium (Y), lanthanides and titanium (Ti),
ii. L_{C} is a monoanionic pi-donor ligand selected from the group consisting of
unsubstituted cyclopentadienide anion,
monoalkyl-substituted cyclopentadienide anions according to the general formula R^{A}Cp⁻, wherein
R^{A} is selected from the group consisting of linear alkyl groups with 1 to 10 carbon atoms and branched alkyl groups with 3 to 10 carbon atoms, and
polyalkyl-substituted cyclopentadienide anions according to the general formula R^{B}R^{C}R^{D}R^{E}R^{F}Cp⁻, wherein
the radicals R^{B}, R^{C}, R^{D}, R^{E} and R^{F} are independently of each other selected from the group consisting of hydrogen (H), linear alkyl groups with 1 to 10 carbon atoms and branched alkyl groups with 3 to 10 carbon atoms,
with the proviso that at least two of the radicals R^{B}, R^{C}, R^{D}, R^{E} and R^{F} are unequal hydrogen (H);
iii. L_{T} is a triazenide anion according to the general formula (R¹—N₃—R²)⁻, wherein the radicals R¹ and R² are independently of each other selected from the group consisting of linear alkyl groups with 1 to 10 carbon atoms and branched alkyl groups with 3 to 10 carbon atoms;
and
iv. L_{Z} is a
a) monoanionic pi-donor ligand which is, independently of the monoanionic pi-donor ligand L_{C}, selected from the group consisting of
unsubstituted cyclopentadienide anion (C₅H₅⁻),
monoalkyl-substituted cyclopentadienide anions according to the general formula R^{A}Cp⁻, wherein
R^{A} is selected from the group consisting of linear alkyl groups with 1 to 10 carbon atoms and branched alkyl groups with 3 to 10 carbon atoms, and
polyalkyl-substituted cyclopentadienide anions according to the general formula R^{B}R^{C}R^{D}R^{E}R^{F}Cp⁻, wherein
the radicals R^{B}, R^{C}, R^{D}, R^{E} and R^{F} are independently of each other selected from the group consisting of hydrogen (H), linear alkyl groups with 1 to 10 carbon atoms and branched alkyl groups with 3 to 10 carbon atoms,
with the proviso that at least two of the radicals R^{B}, R^{C}, R^{D}, R^{E} and R^{F} are unequal hydrogen (H);
or
b) triazenide anion according to the general formula (R¹—N₃—R²)⁻, wherein the radicals R¹ and R² are independently of each other and independently of the triazenide anion L_{T} selected from the group consisting of linear alkyl groups with 1 to 10 carbon atoms and branched alkyl groups with 3 to 10 carbon atoms.

2. Metal complex according to claim 1, wherein the lanthanide is selected from the group consisting of
i. La, Ce, Pr, Nd, Sm, Eu, Gd, Tb, Dy, Ho, Er, Tm, Yb and Lu;
or
ii. La, Ce, Pr, Nd, Sm, Eu, Gd, Tb, Er, Yb and Lu;
or
iii. La, Ce, Pr, Nd, Eu, Gd, Er, Yb and Lu;
or
iv. La, Ce, Nd, Eu, Er and Lu.

3. Metal complex according to claim 1, wherein
i. the monoanionic pi-donor ligand L_{C} is selected from the group consisting of
unsubstituted cyclopentadienide anion (C₅H₅⁻);
monoalkyl-substituted cyclopentadienide anions according to the general formula R^{A}Cp⁻, wherein
the radical R^{A} is selected from the group consisting of methyl, ethyl, propyl, butyl, pentyl, and their isomers;
polyalkyl-substituted cyclopentadienide anions according to the general formula R^{B}R^{C}R^{D}R^{E}R^{F}CP, wherein
the radicals R^{B}, R^{C}, R^{D}, R^{E} and R^{F} are independently of each other selected from the group consisting of hydrogen (H), methyl, ethyl, propyl, butyl, pentyl, and their isomers,
with the proviso that at least two of the radicals R^{B}, R^{C}, R^{D}, R^{E} and R^{F} are unequal hydrogen (H);
and/or
ii. at least one of the radicals R¹ and R² of the triazenide anion L_{T} is selected from the group consisting of linear alkyl groups with 1 to 6 carbon atoms and branched alkyl groups with 3 to 6 carbon atoms.

4. Metal complex according to claim 1, wherein the ligand L_{Z} is a
a) monoanionic pi-donor ligand, wherein the monoanionic pi-donor ligand L_{Z} is selected from the group consisting of
unsubstituted cyclopentadienide anion (C₅H₅⁻);
monoalkyl-substituted cyclopentadienide anions according to the general formula R^{A}Cp⁻, wherein the radical R^{A} is selected from the group consisting of methyl, ethyl, propyl, butyl, pentyl, and their isomers;
polyalkyl-substituted cyclopentadienide anions according to the general formula R^{B}R^{C}R^{D}R^{E}R^{F}CP; wherein the radicals R^{B}, R^{C}, R^{D}, R^{E} and R^{F} are independently of each other selected from the group consisting of hydrogen (H), methyl, ethyl, propyl, butyl, pentyl, and their isomers,
with the proviso that at least two of the radicals R^{B}, R^{C}, R^{D}, R^{E} and R^{F} are unequal hydrogen (H);
or
b) triazenide anion according to the general formula (R¹—N₃—R²)—, wherein at least one of the radicals R¹ and R² of the triazenide anion L_{Z} is selected from the group consisting of linear alkyl groups with 1 to 6 carbon atoms and branched alkyl groups with 3 to 6 carbon atoms.

5. Metal complex according to claim 1, wherein the metal complex exhibits one or more of the following properties:
i. the radical R¹ and the radical R² of the triazenide anion L_{T} are independently of each other selected from the group consisting of methyl, ethyl, propyl, butyl, pentyl, and their isomers;
ii. the radical R¹ and the radical R² of the triazenide anion L_{T} are identical;
iii. L_{Z} is a monoanionic pi-donor ligand, wherein the monoanionic pi-donor ligand L_{C} and the monoanionic pi-donor ligand L_{Z} are identical;
iv. L_{Z} is a triazenide anion according to the general formula (R¹—N₃—R²)⁻, wherein the radical R¹ and the radical R² of the triazenide anion L_{Z} are independently of each other selected from the group consisting of methyl, ethyl, propyl, butyl, pentyl, and their isomers;
V. L_{Z} is a triazenide anion according to the general formula (R¹—N₃—R²)⁻, wherein the radical R¹ and the radical R² of the triazenide anion L_{Z} are identical;
vi. L_{Z} is a triazenide anion according to the general formula (R¹—N₃—R²)⁻, wherein the triazenide anion L_{T} and the triazenide anion L_{Z} are identical.

6. Metal complex according to claim 1, wherein the metal central atom M is selected from the group consisting of Sc, Y, La, Ce, Nd, Eu, Er, Lu and Ti, and
A. the ligand L_{Z} is a monoanionic pi-donor ligand, wherein
i. the monoanionic pi-donor ligand L_{C} or the monoanionic pi-donor ligand L_{Z} is selected
or
ii. the monoanionic pi-donor ligand L_{C} and the monoanionic pi-donor ligand L_{Z} are independently of each other selected from the group consisting of
unsubstituted cyclopentadienide anion (C₅H₅⁻);
monoalkyl-substituted cyclopentadienide anions according to the general formula R^{A}Cp⁻, wherein
the radical R^{A} is selected from the group consisting of methyl, ethyl, n-propyl, iso-propyl, n-butyl, iso-butyl, sec-butyl and tert-butyl;
polyalkyl-substituted cyclopentadienide anions according to the general formula R^{B}R^{C}R^{D}R^{E}R^{F}Cp⁻, wherein
the radicals R^{B}, R^{C}, R^{D}, R^{E} and R^{F} are independently of each other selected from the group consisting of hydrogen (H), methyl, ethyl, n-propyl, iso-propyl, n-butyl, iso-butyl, sec-butyl and tert-butyl,
with the proviso that at least two of the radicals R^{B}, R^{C}, R^{D}, R^{E} and RF, which are unequal hydrogen (H), are identical;
and
the radical R¹ and the radical R² of the triazenide anion L_{T} are independently of each other selected from the group consisting of methyl, ethyl, iso-propyl, iso-butyl, sec-butyl and tert-butyl;
or
B. the ligand L_{Z} is a triazenide anion according to the general formula (R¹—N₃—R²)⁻, wherein
i. the radicals R¹ and R² of one of the two triazenide anions L_{T} and L_{Z} are independently of each other selected from the group consisting of methyl, ethyl, iso-propyl, iso-butyl, sec-butyl and tert-butyl,
or
ii. the radicals R¹ and R² of the triazenide anion L_{T} and the radicals R¹ and R² of the triazenide anion L_{Z} are each independently of each other selected from the group consisting of methyl, ethyl, iso-propyl, iso-butyl, sec-butyl and tert-butyl;
and
the monoanionic pi-donor ligand L_{C} is selected from the group consisting of
unsubstituted cyclopentadienide anion (C₅H₅⁻);
monoalkyl-substituted cyclopentadienide anions according to the general formula R^{A}Cp⁻, wherein
the radical R^{A} is selected from the group consisting of methyl, ethyl, n-propyl, iso-propyl, n-butyl, iso-butyl, sec-butyl and tert-butyl;
polyalkyl-substituted cyclopentadienide anions according to the general formula R^{B}R^{C}R^{D}R^{E}R^{F}CP, wherein
the radicals R^{B}, R^{C}, R^{D}, R^{E} and R^{F} are independently of each other selected from the group consisting of hydrogen (H), methyl, ethyl, n-propyl, iso-propyl, n-butyl, iso-butyl, sec-butyl and tert-butyl,
with the proviso that at least two of the radicals R^{B}, R^{C}, R^{D}, R^{E} and RF, which are unequal hydrogen (H), are identical.

7. Metal complex according to claim 1, wherein
i. the metal complex is vaporisable without decomposition or sublimable without decomposition,
and/or
ii. a molecular weight of the metal complex is less than 600 g/mol.

8. Method for producing a layer which
i. consists of at least one metal M,
wherein the at least one metal M is selected from the group consisting of scandium, yttrium, lanthanides and titanium,
or
ii. contains at least one metal M,
wherein the at least one metal M is selected from the group consisting of scandium, yttrium, lanthanides and titanium,
on a surface of a substrate,
using
at least one metal complex according to the general formula [M(L_{C})(L_{T})(L_{Z})] (I) according to claim 1,
or
a solution comprising the at least one metal complex according to the general formula [M(L_{C})(L_{T})(L_{Z})] (I) according to one or more of claims 1 to 7 and an aprotic non-polar solvent,
comprising the following steps:
A. provision
of the at least one metal complex according to the general formula [M(L_{C})(L_{T})(L_{Z})] (I),
or
of the solution comprising the at least one metal complex according to the general formula [M(L_{C})(L_{T})(L_{Z})] (I) and an aprotic non-polar solvent,
and
B. deposition of the layer which
i. consists of the at least one metal M,
or
ii. contains the at least one metal M,
on the surface of the substrate using the at least one metal complex provided in step A. as a precursor compound.

9. (canceled)

10. Method for producing an electronic component, using
at least one metal complex according to the general formula [M(L_{C})(L_{T})(L_{Z})] (I) according to claim 1,
or
a solution comprising the at least one metal complex according to the general formula [M(L_{C})(L_{T})(L_{Z})] (I) and an aprotic non-polar solvent,
comprising the following steps:
A. provision
of the at least one metal complex according to the general formula [M(L_{C})(L_{T})(L_{Z})] (I),
or
of the solution comprising the at least one metal complex according to the general formula [M(L_{C})(L_{T})(L_{Z})] (I) and an aprotic non-polar solvent,
B. deposition of a layer which
i. consists of the at least one metal M,
or
ii. contains the at least one metal M,
on a surface of a substrate,
and
C. completion of the electronic component.
